(19) United States
(12) Patent Application Publication
(10) Pub. No.: US 2024/0274734 A1
(43) Pub. Date: Aug. 15, 2024

(54) Flexible Solar Panels and Photovoltaic Devices, and Methods and Systems for Producing Them

(71) Applicant: SOLARPAINT LTD., YOKNEAM ILLIT (IL)

(72) Inventors: Ygal Eisenberg, Jerusalem (IL); Eran Maimon, Kibbutz Nahsholim (IL); Yaron Tidhar, Even Yehuda (IL); Asaf Katz, Kibbutz Ma'agan Michael (IL); Hod Yarkoni, Tel Aviv (IL)

(21) Appl. No.: 18/442,127

(22) Filed: Feb. 15, 2024

Related U.S. Application Data
(63) Continuation of application No. PCT/IL2022/050899, filed on Aug. 18, 2022.
(63) Continuation-in-part of application No. 18/129,865, filed on Apr. 2, 2023.
Application No. 18/129,865 is a continuation of application No. PCT/IL2021/051202, filed on Oct. 7, 2021.
Application No. PCT/IL2021/051202 is a continuation-in-part of application No. 17/353,867, filed on Jun. 22, 2021, now Pat. No. 11,978,815.
Application No. 18/129,865 is a continuation-in-part of application No. 17/353,867, filed on Jun. 22, 2021, now Pat. No. 11,978,815.
(63) Continuation-in-part of application No. 17/353,867, filed on Jun. 22, 2021, now Pat. No. 11,978,815.
Application No. 17/353,867 is a continuation-in-part of application No. 16/362,665, filed on Mar. 24, 2019, now Pat. No. 11,081,606.
Application No. 17/353,867 is a continuation-in-part of application No. PCT/IL2019/051416, filed on Dec. 26, 2019.
Application No. PCT/IL2019/051416 is a continuation-in-part of application No. 16/362,665, filed on Mar. 24, 2019, now Pat. No. 11,081,606.
Application No. 18/129,865 is a continuation-in-part of application No. 17/802,335, filed on Aug. 25, 2022.
(63) Continuation-in-part of application No. 18/372,720, filed on Sep. 26, 2023.
Application No. 18/372,720 is a continuation of application No. PCT/IL2022/050339, filed on Mar. 29, 2022.
Application No. PCT/IL2022/050339 is a continuation-in-part of application No. PCT/IL2021/051202, filed on Oct. 8, 2021.
Application No. PCT/IL2021/051202 is a continuation-in-part of application No. PCT/IL2021/051269, filed on Oct. 27, 2021.
Application No. PCT/IL2021/051269 is a continuation-in-part of application No. PCT/IL2022/050030, filed on Jan. 10, 2022.
Application No. PCT/IL2022/050030 is a continuation-in-part of application No. 17/353,867, filed on Jun. 22, 2021, now Pat. No. 11,978,815.
Application No. 18/372,720 is a continuation-in-part of application No. 18/136,359, filed on Apr. 19, 2023.
Application No. 18/136,359 is a continuation of application No. PCT/IL2021/051269, filed on Oct. 27, 2021.
Application No. PCT/IL2021/051269 is a continuation-in-part of application No. 17/353,867, filed on Jun. 22, 2021, now Pat. No. 11,978,815.
Application No. 18/372,720 is a continuation-in-part of application No. 18/217,620, filed on Jul. 3, 2023.
Application No. 18/217,620 is a continuation of application No. PCT/IL2022/050030, filed on Jan. 10, 2022.
(60) Provisional application No. 63/234,727, filed on Aug. 19, 2021.
(60) Provisional application No. 63/238,808, filed on Aug. 31, 2021.
(60) Provisional application No. 63/239,969, filed on Sep. 2, 2021.
(60) Provisional application No. 63/088,535, filed on Oct. 7, 2020.
(60) Provisional application No. 62/785,282, filed on Dec. 27, 2018.
(60) Provisional application No. 62/785,282, filed on Dec. 27, 2018.
(60) Provisional application No. 62/982,536, filed on Feb. 27, 2020.
(60) Provisional application No. 63/167,660, filed on Mar. 30, 2021.
(60) Provisional application No. 63/106,666, filed on Oct. 28, 2020.

(51) Int. Cl. H01L 31/0352; H01L 31/0224; H01L 31/0288; H01L 31/068; H01L 31/18

(52) U.S. Cl. CPC H01L 31/035281; H01L 31/022433; H01L 31/0288; H01L 31/068; H01L 31/1804; H01L 31/1876

(57) ABSTRACT

Improved flexible solar panels and photovoltaic devices, and methods and systems for producing them. A solar cell has non-transcending grooves or trenches, that penetrate some, but not all, of a silicon layer or semiconductor wafer of the solar cell. The non-transcending grooves or trenches are segmenting the solar cell into regions, and provide flexibility and mechanical resilience. Selective and localized region-constrained doping of an opposite polarity is performed at particular regions or locations of a surface or front region of the solar cell; as well as selective and localized placement of metallized electrical contacts. Grooving or trenching operations can be performed via a dopant-containing layer, to prevent or reduce recombination at or near exposed surfaces. A particular layout of metallization is used for producing electrical contacts or “fingers” that are dashed or segmented or spaced-apart; such that grooving or trenching or segmentation lines are located along non-metallized gaps between adjacent contacts and between adjacent rows of contacts.

### CROSS-REFERENCE TO RELATED APPLICATIONS

This patent application is a Continuation of PCT international application number PCT/IL2022/050899, having an international filing date of Aug. 18, 2022, which is hereby incorporated by reference in its entirety.

The above-mentioned PCT/IL2022/050899 claims priority and benefit: from U.S. 63/234,727, filed on Aug. 19, 2021, which is hereby incorporated by reference in its entirety; and from U.S. 63/238,808, filed on Aug. 31, 2021, which is hereby incorporated by reference in its entirety; and from U.S. 63/239,969, filed on Sep. 2, 2021, which is hereby incorporated by reference in its entirety.

This patent application is also a Continuation-in-Part (CIP) of, and claims benefit and/or priority from: patent application U.S. Ser. No. 18/129,865, filed on Apr. 2, 2023, which is hereby incorporated by reference in its entirety.

The above-mentioned U.S. Ser. No. 18/129,865 is a Continuation of PCT international patent application number PCT/IL2021/051202, having an international filing date of Oct. 7, 2021, which is hereby incorporated by reference in its entirety.

The above-mentioned PCT/IL2021/051202 claims priority and benefit: (i) from U.S. 63/088,535, filed on Oct. 7, 2020, which is hereby incorporated by reference in its entirety; and (ii) from U.S. Ser. No. 17/353,867, filed on Jun. 22, 2021, which is hereby incorporated by reference in its entirety.

The above-mentioned U.S. Ser. No. 18/129,865 is also a Continuation-in-Part (CIP) of U.S. Ser. No. 17/353,867, filed on Jun. 22, 2021, which is hereby incorporated by reference in its entirety.

This patent application is also a Continuation-in-Part (CIP) of U.S. Ser. No. 17/353,867, filed on Jun. 22, 2021, which is hereby incorporated by reference in its entirety.

The above-mentioned U.S. Ser. No. 17/353,867 is a Continuation-in-Part (CIP) of U.S. Ser. No. 16/362,665, filed on Mar. 24, 2019, now patent number U.S. Pat. No. 11,081,606 (issued on Aug. 3, 2021), which is hereby incorporated by reference in its entirety; which claims priority and benefit from U.S. 62/785,282, filed on Dec. 27, 2018, which is hereby incorporated by reference in its entirety.

The above-mentioned U.S. Ser. No. 17/353,867 is also a Continuation-in-Part (CIP) of PCT international application number PCT/IL2019/051416, having an international filing date of Dec. 26, 2019, which is hereby incorporated by reference in its entirety.

The above-mentioned PCT/IL2019/051416 claims priority and benefit: (i) from U.S. Ser. No. 16/362,665, filed on Mar. 24, 2019, now patent number U.S. Pat. No. 11,081,606 (issued on Aug. 3, 2021), which is hereby incorporated by reference in its entirety, and (ii) from U.S. 62/785,282, filed on Dec. 27, 2018, which is hereby incorporated by reference in its entirety.

The above-mentioned U.S. Ser. No. 18/129,865 is also a Continuation-in-Part (CIP) of U.S. Ser. No. 17/802,335, filed on Aug. 25, 2022, which is hereby incorporated by reference in its entirety; which is a National Stage of PCT international application number PCT/IL2021/050217, having an international filing date of Feb. 25, 2021, which is hereby incorporated by reference in its entirety; which claims priority and benefit from U.S. 62/982,536, filed on Feb. 27, 2020, which is hereby incorporated by reference in its entirety.

This patent application is also a Continuation-in-Part (CIP) of, and claims benefit and/or priority from: patent application U.S. Ser. No. 18/372,720, filed on Sep. 26, 2023, which is hereby incorporated by reference in its entirety.

The above-mentioned U.S. Ser. No. 18/372,720 is a Continuation of PCT international application number PCT/IL2022/050339, having an international filing date of Mar. 29, 2022, which is hereby incorporated by reference in its entirety.

The above-mentioned PCT/IL2022/050339 claims priority and benefit from U.S. 63/167,660, filed on Mar. 30, 2021, which is hereby incorporated by reference in its entirety.

The above-mentioned PCT/IL2022/050339 also claims priority and benefit from PCT international application number PCT/IL2021/051202, having an international filing date of Oct. 8, 2021, which is hereby incorporated by reference in its entirety.

The above-mentioned PCT/IL2022/050339 also claims priority and benefit from PCT international application number PCT/IL2021/051269, having an international filing date of Oct. 27, 2021, which is hereby incorporated by reference in its entirety.

The above-mentioned PCT/IL2022/050339 also claims priority and benefit from PCT international application number PCT/IL2022/050030, having an international filing date of Jan. 10, 2022, which is hereby incorporated by reference in its entirety.

The above-mentioned PCT/IL2022/050339 also claims priority and benefit from patent application U.S. Ser. No. 17/353,867, filed on Jun. 22, 2021, which is hereby incorporated by reference in its entirety.

The above-mentioned U.S. Ser. No. 18/372,720 is also a Continuation-in-Part (CIP) of U.S. Ser. No. 18/136,359, filed on Apr. 19, 2023, which is hereby incorporated by reference in its entirety. The above-mentioned U.S. Ser. No. 18/136,359 is a Continuation of PCT international application number PCT/IL2021/051269, having an international filing date of Oct. 27, 2021, which is hereby incorporated by reference in its entirety. The above-mentioned PCT/IL2021/051269 claims priority and benefit: (i) from U.S. 63/106,666, filed on Oct. 28, 2020, which is hereby incorporated by reference in its entirety; and also, (ii) from U.S. Ser. No. 17/353,867, filed on Jun. 22, 2021, which is hereby incorporated by reference in its entirety.

The above-mentioned U.S. Ser. No. 18/372,720 is also a Continuation-in-Part (CIP) of U.S. Ser. No. 18/217,620, filed on Jul. 3, 2023, which is hereby incorporated by reference in its entirety; which is a Continuation of the above-mentioned PCT international application number PCT/IL2022/050030, having an international filing date of Jan. 10, 2022, which is hereby incorporated by reference in its entirety.

### FIELD

Some embodiments relate to the field of solar panels and photovoltaic (PV) devices.

### BACKGROUND

The photovoltaic (PV) effect is the creation of voltage and electric current in a material upon exposure to light. It is a physical and chemical phenomenon.

The PV effect has been used in order to generate electricity from sunlight. For example, PV solar panels absorb sunlight or light energy or photons, and generate electricity through the PV effect.

### SUMMARY

Some embodiments provide improved or enhanced solar panels, solar cells, PV cells and/or PV devices, as well as methods and systems for producing them. The solar cells or PV devices may be flexible and/or rollable and/or foldable. For example, a solar cell has non-transcending grooves or trenches, that penetrate some, but not all, of a silicon layer or semiconductor body or semiconductor wafer of the solar cell. The non-transcending grooves or trenches are segmenting the solar cell into regions, and contribute to its flexibility and mechanical resilience. Selective and localized region-constrained doping is performed at particular locations of a surface of the solar cell; as well as selective and localized placement of metallized electrical contacts. Grooving or trenching operations can be performed via a dopant-containing layer, to prevent or reduce recombination at or near exposed surfaces. A particular layout of metallization is used for producing electrical contacts or “fingers” that are dashed or segmented or spaced-apart; such that grooving lines or trenching lines or segmentation lines are located along non-metallized gaps between adjacent contacts and between adjacent rows of contacts.

Some embodiments may provide other and/or additional benefits and/or advantages.

### BRIEF DESCRIPTION OF THE DRAWINGS

FIG. 1A is a schematic illustration of a prior art system, demonstrating a prior art method of producing a solar panel or solar cell.

FIG. 1B is a schematic illustration of a cross-sectional view of a prior art solar cell.

FIG. 1C is a schematic illustration of a cross-sectional view of a solar cell, in accordance with some demonstrative embodiments of the present invention.

FIG. 1D is a schematic illustration of a cross-sectional view of a solar cell, in accordance with some demonstrative embodiments of the present invention.

FIG. 1E is a schematic illustration of a cross-sectional view of a solar cell, in accordance with some demonstrative embodiments of the present invention.

FIG. 1F is a schematic illustration of a cross-sectional view of a solar cell, in accordance with some demonstrative embodiments of the present invention.

FIG. 1G is a schematic illustration of a top-view of a solar cell, in accordance with some demonstrative embodiments of the present invention.

FIG. 1H is a schematic illustration of a top-view of a solar cell, in accordance with some demonstrative embodiments of the present invention.

FIG. 1I is a schematic illustration of a top-view of a solar cell, in accordance with some demonstrative embodiments of the present invention.

FIG. 1J is a schematic illustration of a top-view of a solar cell, in accordance with some demonstrative embodiments of the present invention.

FIG. 1K is a schematic illustration of a top-view of a solar cell, in accordance with some demonstrative embodiments of the present invention.

FIG. 1L is a schematic illustration of a top-view of a solar cell, in accordance with some demonstrative embodiments of the present invention.

FIG. 1M is a schematic illustration of a top-view of a solar cell, in accordance with some demonstrative embodiments of the present invention.

FIG. 1N is a schematic illustration of a top-view of a solar cell, in accordance with some demonstrative embodiments of the present invention.

FIG. 2A is a schematic illustration of an upper view of a front side of a solar cell, having the new architecture of restricted or constrained or selective and localized doped areas or locally-doped regions, in accordance with some demonstrative embodiments of the present invention.

FIG. 2B is a schematic illustration of an upper view of the front side of the solar cell, demonstrating selective “finger” contact placement only at constrained locally-doped areas, in accordance with some demonstrative embodiments of the present invention.

FIG. 2C is a schematic illustration of a selectively locally-doped surface of a solar cell or PV cell, in accordance with some demonstrative embodiments.

FIG. 2D is a schematic illustration of another selectively locally-doped surface of a solar cell or PV cell, in accordance with some demonstrative embodiments.

FIG. 2E is a schematic illustration of intended dicing lines or cutting lines or etching lines of a solar cell, in accordance with some demonstrative embodiments of the present invention.

FIG. 3A is a schematic illustration of a portion of a cross sectional view of a prior art Passivated Emitter and Rear Contact (PERC) or Passivated Emitter and Rear Cell (PERC) solar cell.

FIG. 3B is a schematic illustration of a portion of a cross sectional view of a PERC solar cell having trenches across its base region, in accordance with some demonstrative embodiments of the present invention.

FIG. 3C is a schematic illustration of a portion of a cross sectional view of a PERC solar cell having trenches across its front region, in accordance with some demonstrative embodiments of the present invention.

FIG. 3D is a schematic illustration of a portion of a cross sectional view of a PERC solar cell, in which a first set of trenches are engraved or formed in the front region/the N-type layer, and a second set of trenches are engraved or formed in the base region/the P-type layer, in accordance with some demonstrative embodiments of the present invention.

FIG. 3E is a schematic illustration of a portion of a cross sectional view of a PERC solar cell, having trenches across its base region, and further showing a possible break line that extends from the end of the trench to the nearby front region, in accordance with some demonstrative embodiments of the present invention.

FIG. 3F is a schematic illustration of a cross-sectional view of a portion of a PERC solar cell, wherein a trench is about to be engraved at its base region (its rear side) by using a laser beam that operates via a dopant coating layer, in accordance with some demonstrative embodiments of the present invention.

FIG. 3G is a schematic illustration of a cross-sectional view of a portion of a PERC solar cell, wherein a trench is being engraved at its base region (its rear side) by using a laser beam that operates via a dopant coating layer, in accordance with some demonstrative embodiments of the present invention.

FIG. 3H is a schematic illustration of a resulting PERC solar cell, having a trench in the back region (rear surface), wherein the trench was engraved after surface doping, in accordance with some demonstrative embodiments of the present invention.

FIGS. 4A to 4D are photographs demonstrating stages in the process of treating a PERC solar cell, prior to performing dicing operations, in accordance with some demonstrative embodiments of the present invention.

FIG. 5A is a schematic illustration of a plan of electrical contacts metallization layout for a solar cell, in accordance with some demonstrative embodiments.

FIG. 5B is a photograph of an upper-side view of a solar cell after placement of the metallization layout of electrical contacts, in accordance with some demonstrative embodiments.

FIG. 5C is a photograph of a portion of a solar cell in accordance with some demonstrative embodiments; showing a set of discrete, spaced-apart, segmented or dashed, metallization “fingers” or electrical contacts arranged in generally-parallel rows.

FIG. 5D is a photograph of a portion of a prior art solar cell, in which electrical contacts or metallization “fingers” are structured as continuous rows, wherein each prior art “finger” is a full, elongated, continuous line or wire of electrical contact; and wherein there is exactly one finger, and not a plurality of spaced-apart/segmented/dashed fingers, in each row.

FIG. 5E is a schematic illustration of a prior art solar cell, in which electrical contacts or metallization “fingers” are configured as continuous rows; such that each “finger” is a full, elongated, continuous line or wire of electrical contact; and wherein there is exactly one finger, and not a plurality of spaced-apart/segmented/dashed fingers, in each row.

FIG. 5F is a schematic illustration of a solar cell in accordance with some demonstrative embodiments of the present invention; showing a set of discrete, spaced-apart, segmented or dashed, metallization “fingers” or electrical contacts arranged in generally-parallel rows.

FIG. 5G is a schematic illustration demonstrating how applying Trenching/Grooving/Segmenting rows and columns would affect a prior art solar cell, in which each row has a single, elongated, non-dashed, non-segmented, electrical contact or metallization “finger”.

FIG. 5H is a schematic illustration demonstrating the innovative utilization of Trenching/Grooving rows and columns on an innovative solar cell, in which each row has multiple, discrete or dashed or segmented or spaced-apart or non-continuous, electrical contacts or metallization “fingers”, in accordance with some demonstrative embodiments of the present invention.

FIG. 6 is a photograph of a flexible solar cell with an innovative metallization layout, after singulation (or segmentation, or grooving, or trenching), of the solar cell into segments, in accordance with some demonstrative embodiments of the present invention.

FIG. 7 is a schematic illustration of a rear side of a solar cell, having a metallization layout that is intended to enable formation of a flexible and mechanically resilient PERC solar cell, in accordance with some demonstrative embodiments of the present invention.

FIG. 8A is a schematic illustration of another layout plan for contacts metallization for another solar cell, in accordance with some demonstrative embodiments of the present invention.

FIG. 8B is an enlarged (or zoomed-in) view of a portion of the layout plan, to more clearly show its details and structure, in accordance with some demonstrative embodiments of the present invention.

FIG. 8C is a photograph of a portion of the layout plan of a flexible solar panel, and further demonstrates locally-doped regions that were subject to localized doping, as well as demonstrating the in-between regions that were not subject to localized doping, in accordance with some demonstrative embodiments of the present invention.

FIG. 9 is a photograph of a flexible solar cell demonstrating metallization contacts or “fingers”, as well as wires, in accordance with some demonstrative embodiments.

### DETAILED DESCRIPTION OF SOME DEMONSTRATIVE EMBODIMENTS

The Applicants have realized that conventional solar panels are typically rigid, heavy, cumbersome, brittle and/or fragile units, that are typically installed on roofs or in other locations (e.g., a solar energy park, a solar energy farm, a solar power plant).

The Applicants have realized that there is a need to improve and/or enhance the structure and/or configuration and/or production process of solar panels and other PV devices; in order to improve or enhance their efficiency, durability, mechanical resilience or durability, thermal resilience or durability, physical resilience or durability, mechanical strength, modularity, and other characteristics; and/or in order to allow a more versatile utilization of such solar panels and other PV devices.

Description of Some Embodiments Related to Mini-Cells with Selective Localized Doping-Regions:

Some embodiments provide an improved structure or configuration of PV devices or solar panels; and particularly, a PV device or solar panels that has mini-cells or miniature PV cells, or an array or matrix of such miniature PV cells, which have selective or localized doped areas or regions that are pre-defined or constrained or limited or restricted in accordance with a particular structure or pattern or configuration; and which have a particular arrangement or architecture or positioning of electrical contacts on the surface(s) of such solar panels or PV devices.

In accordance with some embodiments, a PV cell or solar panel has an architecture or pattern or structure of solar cells having restricted or constrained or limited doped areas or doping regions; for example, having P-N junctions that are not covering the entire surface of one side of the solar panel or solar cell, but rather, having P-N junctions that cover only some (but not all) of the entire surface of one side of the solar panel or solar cell. The restricted or the constrained doped areas or doping regions may be distributed across the solar cell (e.g., for example, a silicon wafer based solar cell) in accordance with a particular pattern or structure, in accordance with a regular and/or irregular arrangement, in accordance with an arrangement that may be pre-defined or may be at least partially random or pseudo-random, or in accordance with a pre-defined arrangement pattern or structure, or the like.

Optionally, some embodiments may be utilized in conjunction with PV devices and/or solar panels and/or components and/or methods that are described in patent number U.S. Pat. No. 11,081,606, titled “flexible and rollable photovoltaic cell having enhanced properties of mechanical impact absorption”, which is hereby incorporated by reference in its entirety; and/or in conjunction with components, structures, devices, methods, systems and/or techniques that are described in patent application number U.S. Ser. No. 17/353,867, filed on Jun. 22, 2021, published as US 2021/0313478, which is hereby incorporated by reference in its entirety; and/or with solar panels or solar cells or PV devices that are singulated or segmented, or that are flexible and/or rollable and/or foldable, and/or that include “blind gaps” or non-transcending gaps or craters. Some embodiments may provide a flexible and rollable PV cell or solar cell; wherein a silicon body or semiconductor body or semiconductor substrate or semiconductor wafer has non-transcending craters or “blind gaps” that penetrate into between 80 percent and 99 percent of a total thickness of the semiconductor body (or wafer, or substrate), and that do not penetrate into an entirety of the total thickness of the semiconductor body (or wafer, or substrate); wherein said non-transcending craters or “blind gaps” increase flexibility/or and mechanical resilience and/or mechanical shock absorption of the PV cell. In some embodiments, some, or most, or all of the non-transcending craters or “blind gaps” contain a filler material having mechanical force absorption properties, which provides mechanical shock absorption properties and/or mechanical force dissipation properties to the PV cell.

The Applicants have realized that the process of producing some types of flexible solar panels may, in some situations, cause some damage or partial damage upon the P-N junction interface of such items; and that there is a need to produce solar panels and PV devices, which may be flexible and/or rollable and/or foldable, and which have enhanced properties of mechanical resilience and/or mechanical shock absorption and/or mechanical forces dissipation, without inflicting damage on the P-N junctions or the P-N interface, and/or while inflicting a reduced damage on such P-N junctions or P-N interface.

The Applicants have further realized that it may be beneficial to provide a PV device, which may be flexible and/or rollable and/or foldable, and which have enhanced properties of mechanical resilience and/or mechanical shock absorption and/or mechanical forces dissipation; which is structured as an array or matrix of autonomous, independent, PV/solar cells or miniature PV/solar cells; rather than providing a single PV device (or solar panel) that is singulated or segmented via “blind gaps” or non-transcending gaps or craters into a plurality of regions; and that such structure of a solar panel or PV device may be utilized for sensors or for a variety of other purposes.

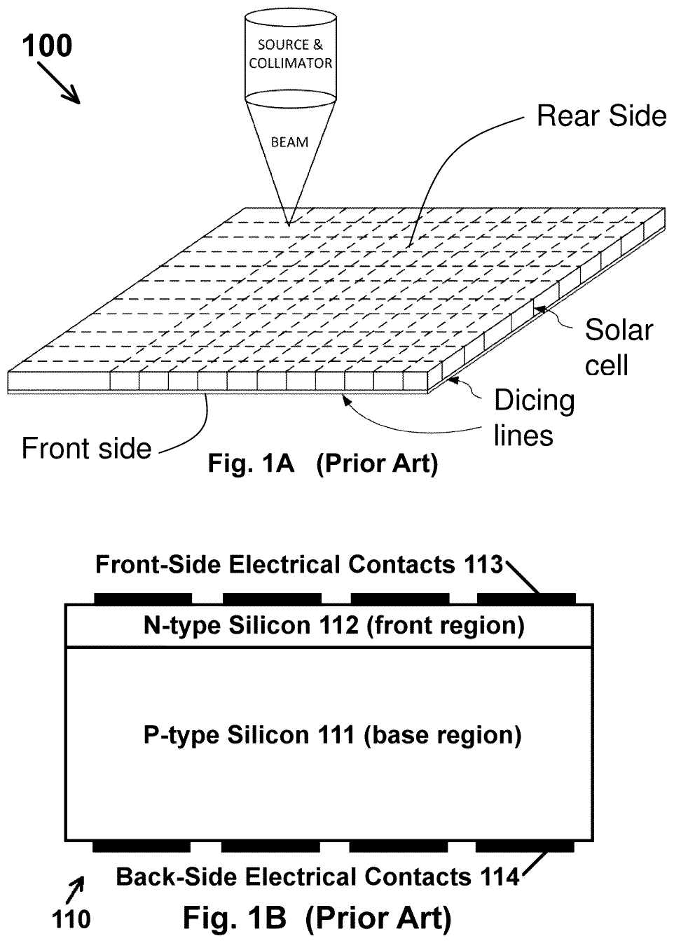

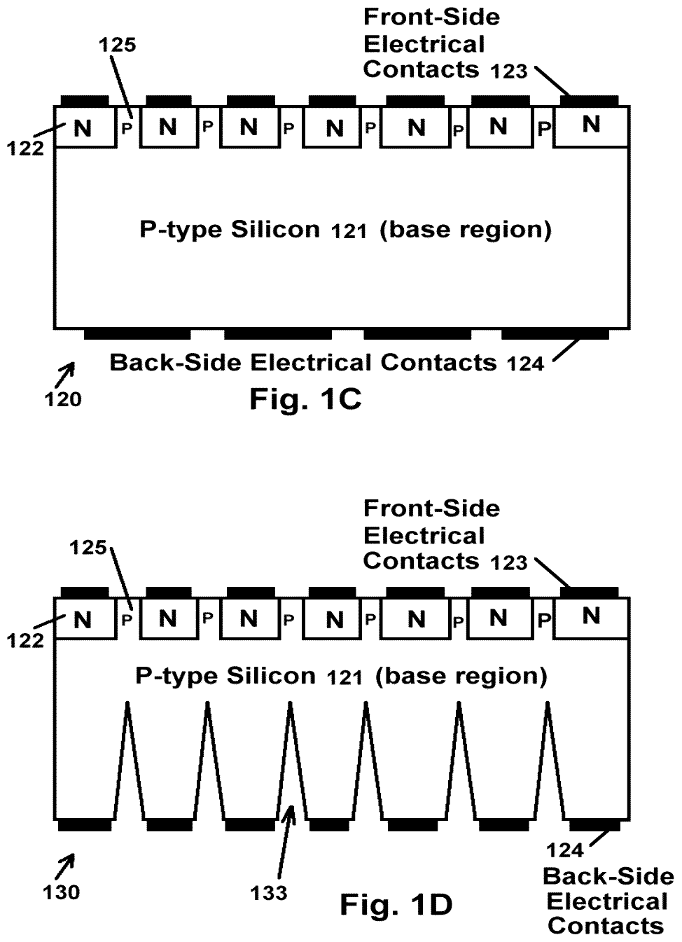

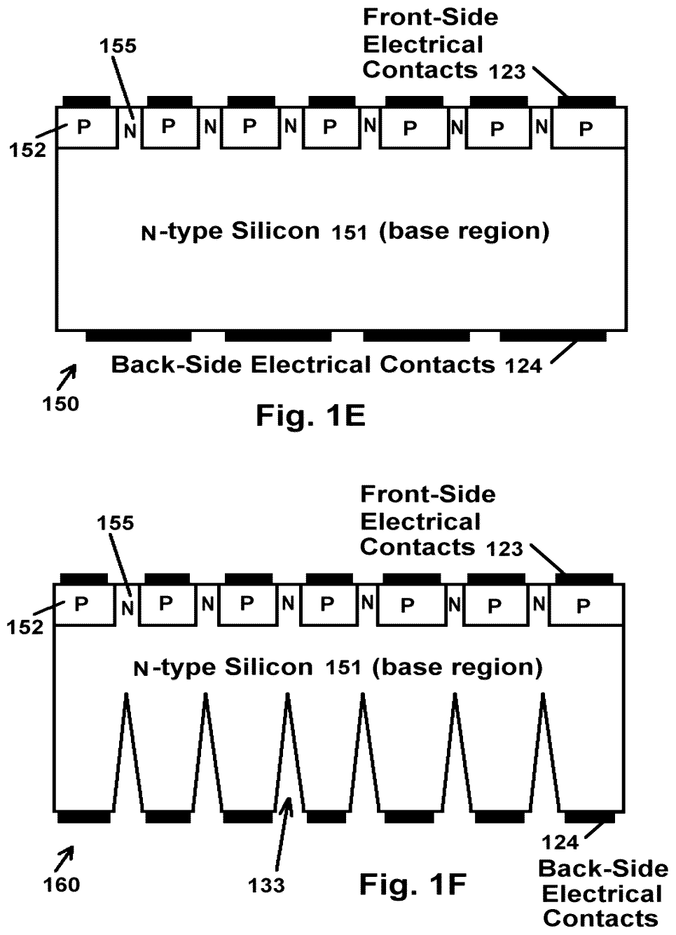

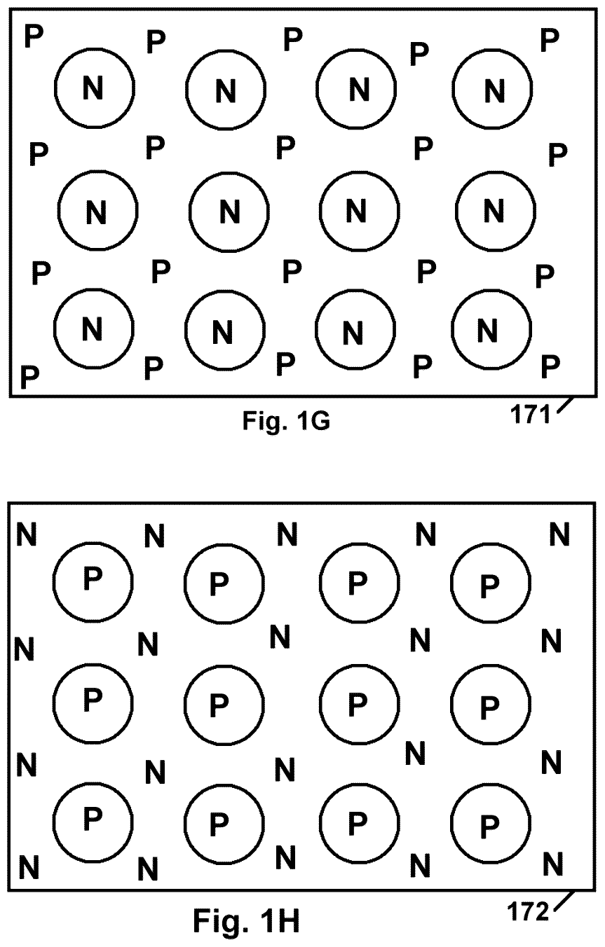

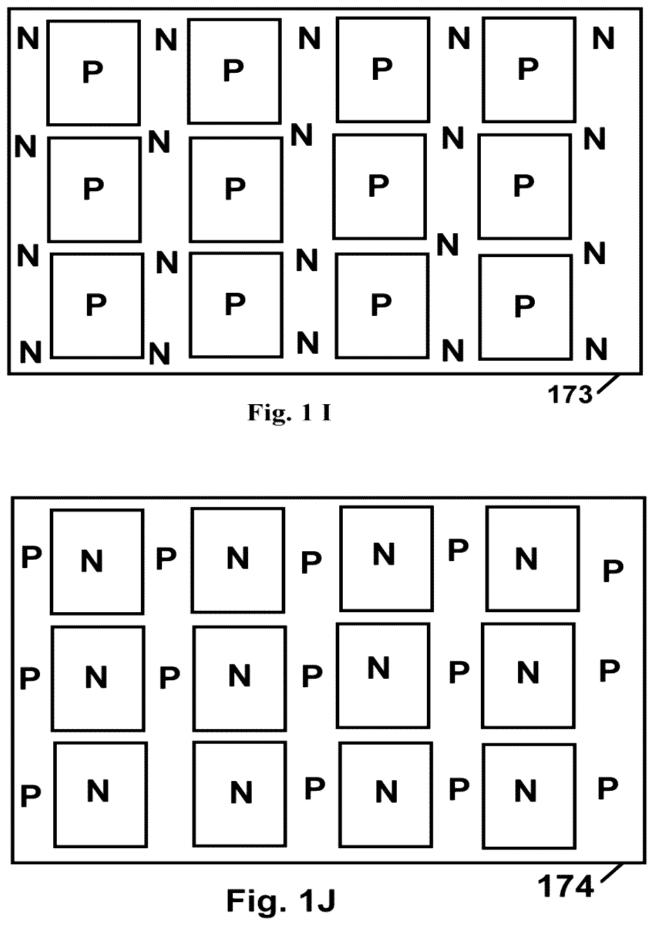

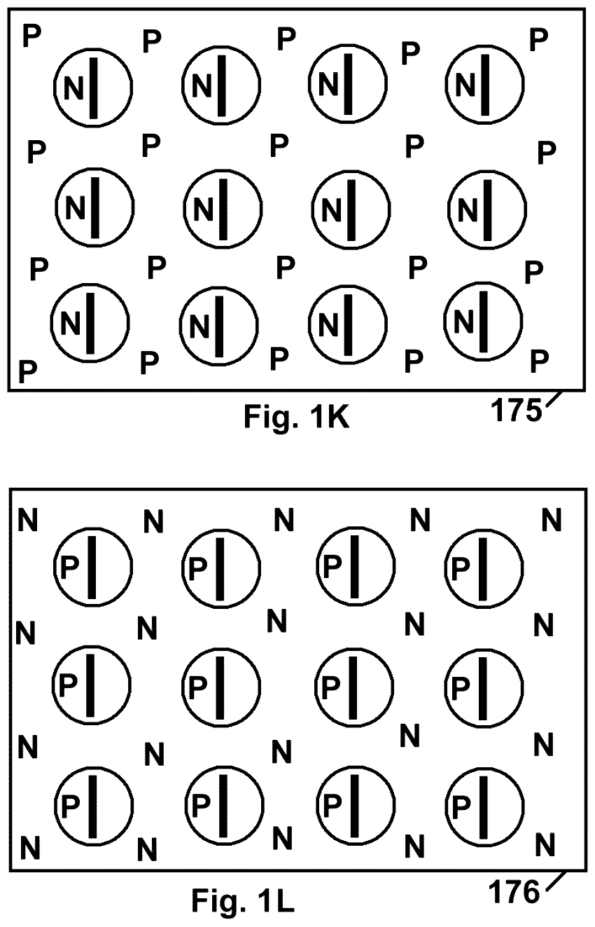

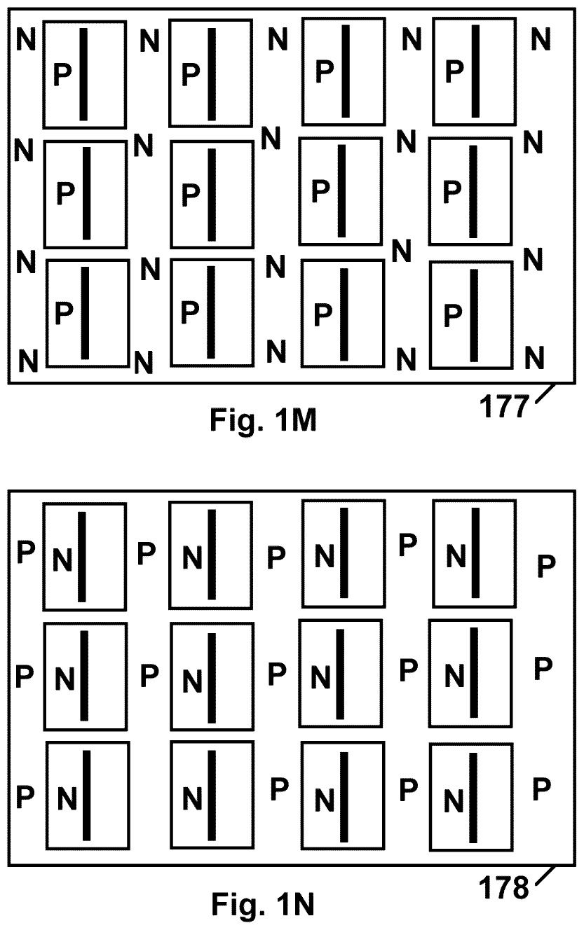

Reference is made to FIG. 1A, which is a schematic illustration of a prior art system 100, demonstrating a prior art method of producing a solar panel or solar cell. As shown, the rear surface of the solar panel or solar cell may be subject to a singulation or segmentation or trenching or grooving process, to create an array or a mesh of nearby PV regions that have “blind gaps” or non-transcending gaps or craters among them, while still sharing at least 1% of the thickness of a single, unified, semiconductor wafer or substrate that runs along all of those regions and still remains intact; and this may be followed by breaking or cutting the large array or mesh into smaller PV regions. In some embodiments, for example, each flexible solar cell or solar module may be in the size of approximately 25×25 cm, or approximately 20×20 cm, or approximately 18×18 cm, or other suitable sizes.

The Applicants have realized that such prior art system, while being useful for producing some types of flexible and/or rollable solar panels, may cause the P-N junctions or the P-N junction interface to become exposed or opened to the outer surface or the outer nearby environment, without any isolation, thereby possibly reducing the efficiency of the PV electric generation and/or causing energy losses.

In accordance with some embodiments of the present invention, a system and a method are provided to produce a solar cell or solar panel, by firstly preparing or using an architecture or structure that can be more adequately utilized as a basis for a diced or singulated or segmented or trenched or grooved solar cell or solar panel; and such that cutting and/or breaking of the array does not cause cutoffs in the P-N junction interface, and is not harmful (or, is less harmful) to the solar cell's functionality or efficiency.

Reference is made to FIG. 1B, which is a schematic illustration of a cross-sectional view of a prior art solar cell 110. As shown, a P-type silicon 111 is the base layer or the base region or the bulk region or the silicon bulk; and the entirety of a top surface of that P-type silicon is doped with an N-type dopant to become an N-type silicon layer 112. Accordingly, a P-N junction 113 or P-N interface exists, at (or near) the interface or the border that is between the P-type silicon 111 and the N-type silicon layer 112. Front-side electrical contacts 113 are spread on the top side; back-side electrical contacts 114 are implemented as discrete wires that run along the back side.

Reference is made to FIG. 1C, which is a schematic illustration of a cross-sectional view of a solar cell 120, in accordance with some demonstrative embodiments of the present invention. As shown, a P-type silicon 121 is the base layer or the base region; however, not the entirety of a top surface of that P-type silicon is doped with an N-type dopant to become an N-type silicon layer; but rather, only particular, localized, pre-defined and constrained regions of the top surface of that P-type silicon are selectively doped with an N-type dopant to become N-type top-side regions 122, that occupy some (or most) but not all of the top-side surface. Between those N-type top-side regions, there remain interim top-side regions 125 that remain P-type silicon that was not doped with the N-type dopant, and that did not become N-type silicon.

Furthermore, in accordance with some embodiments, the back-side electrical contacts 124 may run as discrete elongated metal wires beneath the back-side; however, the top-side or front-side electrical contacts 123 are, innovatively, structured and sized and positioned to be only and precisely on top of the N-type top-side regions 122; and front-side electrical contacts are not placed on top of the interim top-side regions 125 that were not doped with the N-type dopant and that remained as top-side P-type silicon regions. Alternatively, in other embodiments, the top-side or front-side electrical contacts 123 are, innovatively, structured and sized and positioned to be Not on top of the N-type top-side regions 122; but rather, the front-side electrical contacts 123 are placed precisely on top of the interim top-side regions 125 that were not doped with the N-type dopant and that remained as top-side P-type silicon regions. In each one of these two types of implementations, each of the front-side electrical contacts 123 is placed or positioned either (i) on top of the N-type top-side regions 122, or (ii) on top of the interim top-side regions 125 that were not doped with the N-type dopant and that remained as top-side P-type silicon regions; but not continuously on both of these opposite polarity type of regions.

The Applicants have realized that the particular configuration and structure, of the selectively-localized N-doped regions at the top surface of the P-type silicon, as well as the precise placement of the front-side/top-side electrical contacts exactly on top of those selectively-localized top-side N-doped regions, may provide one or more benefits or advantages. For example, realized the Applicants, the regions 125 that were not N-doped, and that are not covered with an electrical contact or “finger”, are suitable for performing through them (or exactly beneath them) a process of mechanical segmentation or singulation or dicing or trenching or grooving, to create non-transcending gaps or craters or grooves or trenches that penetrate some (but not all) of the thickness of the silicon; and such non-transcending craters or grooves or trenches or “blind gaps” (by themselves; or when filled with a suitable filler material) may contribute to flexibility or flexing capability of the solar cell 120, or may assist the solar cell 120 to be flexible and/or rollable and/or bendable and/or foldable without being damaged or broken, and/or may absorb mechanical shocks and/or mechanical forces, and/or may dissipate mechanical shocks and/or mechanical forces, and/or may increase the durability and/or mechanical resilience of the solar cell 120. d

Reference is made to FIG. 1D, which is a schematic illustration of a cross-sectional view of a solar cell 130, in accordance with some demonstrative embodiments of the present invention. Solar cell 130 may be similar to solar cell 120 described above; however, grooves or trenches 133 (or craters, or “blind gaps”, or non-transcending gaps) penetrate upwardly from the back side of the silicon, penetrating into some but not all of the depth (or thickness) of the silicon; for example, penetrating into 50 to 90 percent, or 50 to 99 percent, of the entire thickness of the silicon; and leaving intact and non-penetrated at least 1 percent of the total thickness of the silicon. The back-side electrical contacts 124 are positioned in between the openings of such grooves or trenches. Optionally, each of the trenches 133, or some of them, or most of them, may be filled (partially or entirely) with a filler material, which may assist in absorbing and/or dissipating mechanical shocks, and/or which may contribute to mechanical resilience and/or durability, and/or which may contribute to thermal resilience and/or durability.

Reference is made to FIG. 1E, which is a schematic illustration of a cross-sectional view of another solar cell 150, in accordance with some demonstrative embodiments of the present invention. As shown, an N-type silicon 151 is the base layer or the base region; however, not the entirety of a top surface of that N-type silicon is doped with a P-type dopant to become a P-type silicon layer; but rather, only particular, localized, pre-defined and constrained regions of the top surface of that N-type silicon are selectively doped with a P-type dopant to become P-type top-side regions 152, that occupy some (or most) but not all of the top-side surface. Between those P-type top-side regions, there remain interim top-side regions 155 that remain N-type silicon that was not doped with the P-type dopant, and that did not become P-type silicon.

Reference is made to FIG. 1F, which is a schematic illustration of a cross-sectional view of a solar cell 160, in accordance with some demonstrative embodiments of the present invention. Solar cell 160 may be similar to solar cell 150 described above; however, grooves or trenches 133 (or craters, or “blind gaps”, or non-transcending gaps) penetrate upwardly from the back side of the silicon, penetrating into some but not all of the depth (or thickness) of the silicon; for example, penetrating into 50 to 90 percent, or 50 to 99 percent, of the entire thickness of the silicon; and leaving intact and non-penetrated at least 1 percent of the total thickness of the silicon. The back-side electrical contacts 124 are positioned in between the openings of such grooves or trenches. Optionally, each of the trenches 133, or some of them, or most of them, may be filled (partially or entirely) with a filler material, which may assist in absorbing and/or dissipating mechanical shocks, and/or which may contribute to mechanical resilience and/or durability, and/or which may contribute to thermal resilience and/or durability.

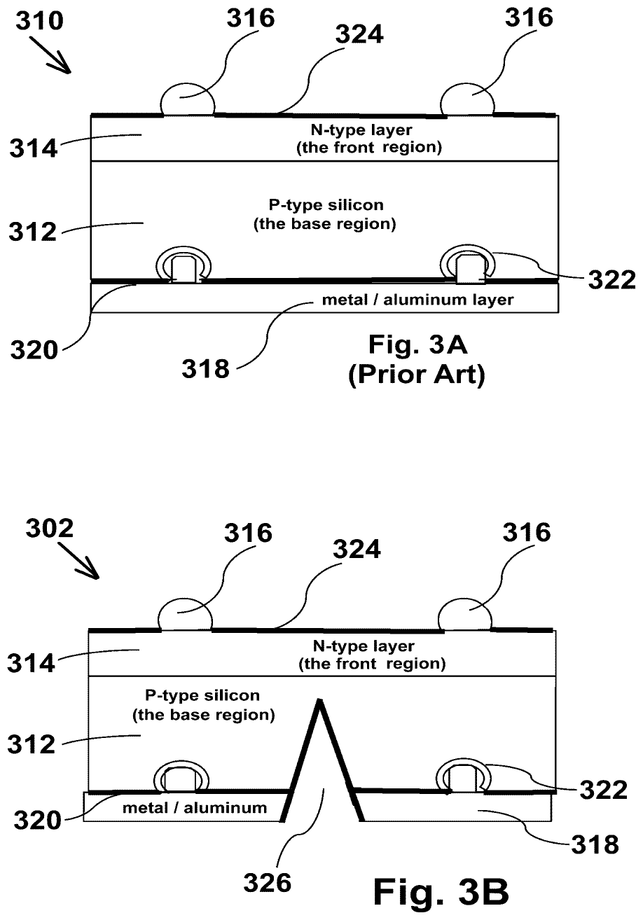

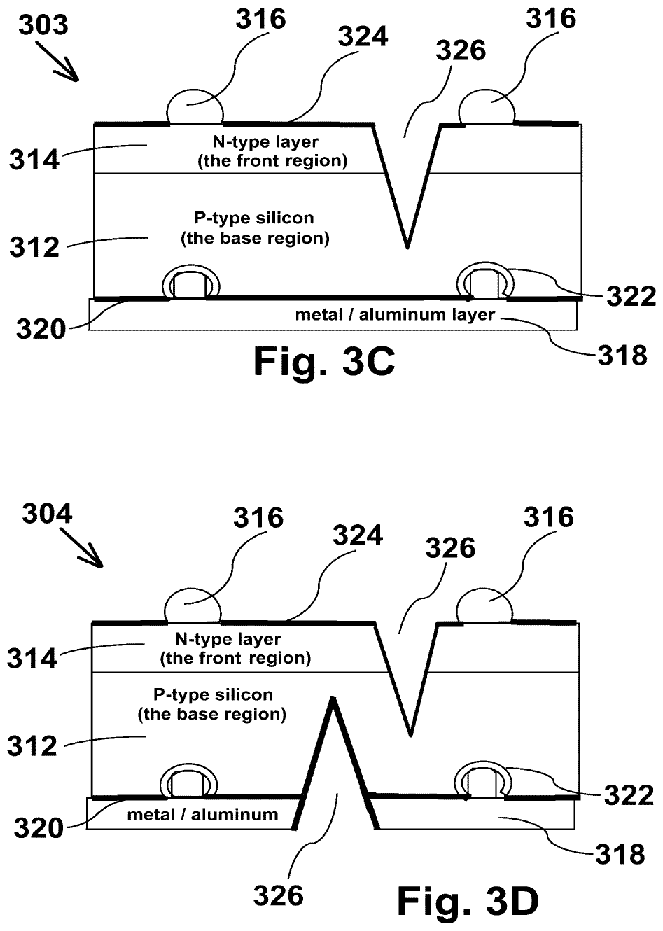

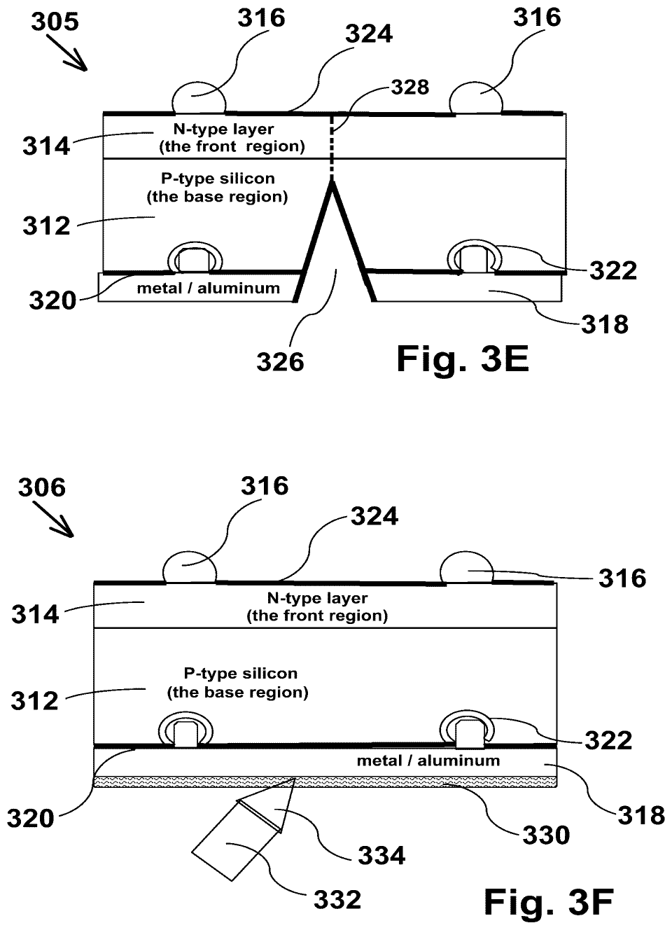

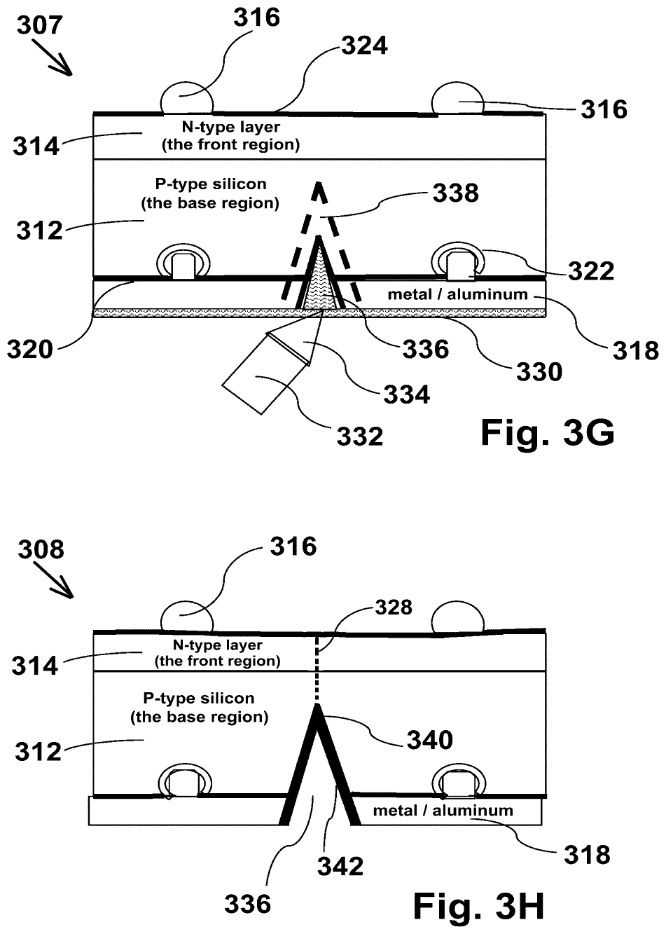

It is noted that with regard to any of FIGS. 1C to IF, as well as other drawings (e.g., FIGS. 3B to 3H), in some embodiments the “sunny side” of the PV cell (the side or the surface that is intended to be directly facing the light source) may be at the top side of the drawing, whereas the “dark side” (which is the opposite side to the “sunny side”) may be at the bottom side of the drawing; however, in some embodiments, the structure may be vertically flipped, such that the “sunny side” of the PV cell (the side or the surface that is intended to be directly facing the light source) may be at the bottom side of the drawing, whereas the “dark side” (which is the opposite side to the “sunny side”) may be at the top side of the drawing. In some other embodiments, the PV cell may be a double-sided PV cell, which may be configured to absorb light at both of its opposite surfaces.

Reference is made to FIG. 1G, which is a schematic illustration of a top-view of a solar cell 171, in accordance with some demonstrative embodiments of the present invention. Solar cell 171 is formed, generally, of a P-type silicon bulk; and its top surface has particular, pre-defined, constrained, localized, regions (denoted with N) that were doped with an N-type dopant (e.g., phosphorus) and are top-side N-doped regions. For demonstrative purposes, each of the pre-defined N-doped regions is shown as a circular region; however, the selectively-doped regions may have other suitable shapes (e.g., square, rectangle, triangle, oval, polygon).

Reference is made to FIG. 1H, which is a schematic illustration of a top-view of a solar cell 172, in accordance with some demonstrative embodiments of the present invention. Solar cell 170 is formed, generally, of an N-type silicon bulk; and its top surface has particular, pre-defined, constrained, localized, regions (denoted with P) that were doped with a P-type dopant (e.g., boron) and are top-side P-doped regions. For demonstrative purposes, each of the pre-defined P-doped regions is shown as a circular region; however, the selectively-doped regions may have other suitable shapes (e.g., square, rectangle, triangle, oval, polygon).

Reference is made to FIG. 1I, which is a schematic illustration of a top-view of a solar cell 173, in accordance with some demonstrative embodiments of the present invention. Solar cell 173 is formed, generally, of an N-type silicon bulk; and its top surface has particular, pre-defined, constrained, localized, regions (denoted with P) that were doped with a P-type dopant (e.g., boron) and are top-side P-doped regions. For demonstrative purposes, each of the pre-defined P-doped regions is shown as a rectangular region; however, the selectively-doped regions may have other suitable shapes.

Reference is made to FIG. 1J, which is a schematic illustration of a top-view of a solar cell 174, in accordance with some demonstrative embodiments of the present invention. Solar cell 174 is formed, generally, of a P-type silicon bulk; and its top surface has particular, pre-defined, constrained, localized, regions (denoted with N) that were doped with an N-type dopant (e.g., boron) and are top-side N-doped regions. For demonstrative purposes, each of the pre-defined N-doped regions is shown as a rectangular region; however, the selectively-doped regions may have other suitable shapes.

Reference is made to FIG. 1K, which is a schematic illustration of a top-view of a solar cell 175, in accordance with some demonstrative embodiments of the present invention. Solar cell 175 is generally similar to solar cell 171 described above; and it further shows the top-side electrical contacts or “fingers”, that are placed precisely on top of the localized top-side N-doped regions; and are not placed on top of the in-between regions of the top surface that were not N-doped and that remained P-doped like the bulk of that P-type silicon.

Reference is made to FIG. 1L, which is a schematic illustration of a top-view of a solar cell 176, in accordance with some demonstrative embodiments of the present invention. Solar cell 176 is generally similar to solar cell 172 described above; and it further shows the top-side electrical contacts or “fingers”, that are placed precisely on top of the localized top-side P-doped regions; and are not placed on top of the in-between regions of the top surface that were not P-doped and that remained N-doped like the bulk of that N-type silicon.

Reference is made to FIG. 1M, which is a schematic illustration of a top-view of a solar cell 177, in accordance with some demonstrative embodiments of the present invention. Solar cell 177 is generally similar to solar cell 173 described above; and it further shows the top-side electrical contacts or “fingers”, that are placed precisely on top of the localized top-side P-doped regions; and are not placed on top of the in-between regions of the top surface that were not P-doped and that remained N-doped like the bulk of that N-type silicon.

Reference is made to FIG. 1N, which is a schematic illustration of a top-view of a solar cell 178, in accordance with some demonstrative embodiments of the present invention. Solar cell 178 is generally similar to solar cell 174 described above; and it further shows the top-side electrical contacts or “fingers”, that are placed precisely on top of the localized top-side N-doped regions; and are not placed on top of the in-between regions of the top surface that were not N-doped and that remained P-doped like the bulk of that P-type silicon.

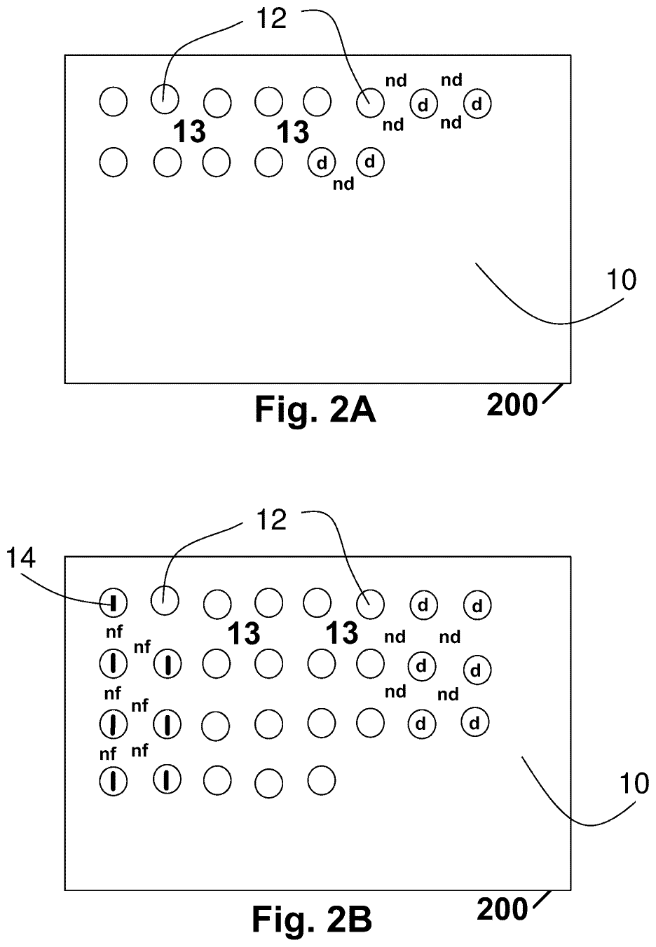

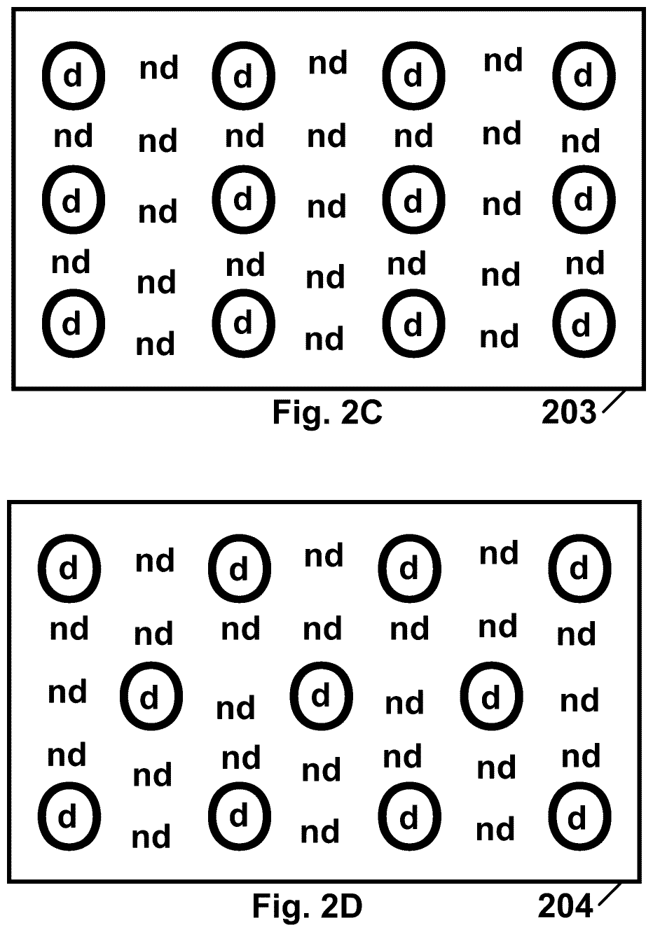

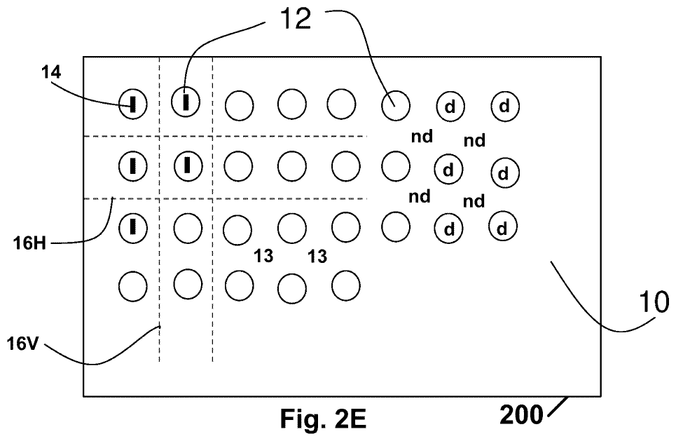

Reference is made to FIG. 2A, which is a schematic illustration of an upper view of a front side 200 of a solar cell, having the new architecture of restricted or constrained or selective and Locally Doped areas, in accordance with some demonstrative embodiments of the present invention. Regions 12 or regions marked with “d” are those that were selectively and particularly doped with a dopant that has opposite polarity to the polarity of the bulk silicon (or the back region). Regions 13 or regions marked with “nd” are those that maintained the native polarity of the silicon bulk, and that were not selectively treated with the dopant of the opposite polarity. For example, in some embodiments, regions 12 or regions “d” are N-doped, whereas regions 13 or regions “nd” are P-doped. In other embodiments, regions 12 or regions “d” are P-doped, whereas regions 13 or regions “nd” are N-doped.

For example, a substrate 10 (e.g., semiconductor or silicon) that is intended to be a part of a solar cell or a PV device, comprises multiple layers of a semiconductor wafer. In accordance with some embodiments, in order to prepare the substrate 10 to be activated and operational as a solar cell or PV device, boron (or other P-type dopant) is doped in the silicon wafer or the semiconductor substrate this is happening during the silicon crystal ingot growth, even before slicing it to wafers, to create a P-type silicon bulk. Then, only particular, pre-defined, constrained, regions of the top surface of that P-type silicon bulk, are doped with phosphorus (or other N-type dopant), to create the N-type regions on that top surface; that are separated with small gaps that were not doped with any N-type dopant and that remain P-type silicon.

In other embodiments, the polarities may be exchanged: for example, in order to prepare the substrate 10 to be activated and operational as a solar cell or PV device, phosphorus (or other N-type dopant) is doped in the silicon wafer or the semiconductor substrate, to create an N-type silicon bulk. Then, only particular, pre-defined, constrained, regions of the top surface of that N-type silicon bulk, are doped with boron (or other P-type dopant), to create the P-type regions on that top surface; that are separated with small gaps that were not doped with any P-type dopant and that remain N-type silicon.

The selective, region-constrained, doping of the top surface of the silicon bulk, may be performed using one or more suitable methods; for example, using a mask or template that has holes or openings or apertures only at the regions that are intended to receive the dopant treatment, and covering the other regions or the regions that are in between.

In some embodiments, the P-N junctions may be formed by (or may be) heterojunctions; for example, by deposition of Amorphous Silicon (a-Si) or non-crystalline Silicon on the surfaces of a silicon wafer. Other solar cell technologies may be used in conjunction with some or all the features that are described above and/or herein, for example, forming a triple junction, using silicon on glass, using Cadmium Telluride (CdTe), using Gallium Arsenide (GaAs), using copper indium gallium selenide (CIGS), using Organic PV (OPV) components, using Perovskite, using Perovskite-Silicon tandem, using other tandem, using Germanium (Ge), and/or other suitable types; as long as a particular area of the junction (which may be monojunction or heterojunction) can be defined.

In some embodiments, the doping (e.g., with phosphorous or boron) is performed in a selective and controlled manner, for example, by gas phase deposition or vapor phase doping performed at particular locations 12, followed by a thermal drive-in (thermal diffusion) process (e.g., to allow gradual diffusion of the source dopants into the silicon wafer with a concentration gradient), or by other methods such as laser doping, liquid phase doping, gas based doping, vapor phase doping, solid based doping, or the like. Various doping techniques may be used, including (for example) empty space diffusion, inter lattice diffusion, diffusion from a gas phase or using a carrier gas, diffusion with a solid source diffusion with a liquid source, doping using an alloy, ion implantation, or the like.

In a demonstrative embodiment, a mask or template may be applied or positioned or deposited onto the silicon bulk or wafer. The mask may be a surface having particular and pre-defined openings or holes or apertures in accordance with a particular pattern or arrangement; the openings being formed by a cutting machine, by laser ablation, by laser lithography or photolithography, using inkjet or similar technologies, or the like.

The dopant material(s), or the dopant-containing layer, which is utilized for the selective, localized, region-constrained doping of the top surface of the silicon bulk, is then deposited or sprayed or applied or added onto (or through) that mask or template of that surface; such that the dopant reaches, and is deposited only at, the regions of the top surface of the silicon that are beneath the openings or holes in the mask; whereas nearby regions of the top surface that are covered by the mask without an opening, do not receive the deposition of the dopant. Then, thermal diffusion or high-temperature diffusion may be performed. The utilization of such mask or template, with the pre-defined holes or openings or apertures, allows to achieve selective, region-restricted or region-constrained, doping of that surface of the silicon or semiconductor wafer or substrate.

In some embodiments, alternatively and/or optionally, doping paste or dopant-containing paste is printed or deposited onto the top surface of the silicon or wafer, by depositing or spraying or spreading such dopant paste in drops at a pre-defined distance from each other, thereby creating dopant deposition areas that are separated from each other with no-deposition areas; without necessarily utilizing a mask or a template. The deposition or spraying or spreading of the dopant paste may be performed in accordance with a pre-defined pattern or map, which indicates at which locations of the target wafer will the dopant paste be deposited, and which nearby locations of the target wafer will not be subject to covering with the dopant paste; thereby achieving selective, region-restricted or region-constrained, doping of that surface of the semiconductor wafer or substrate.

In some embodiments, alternatively and/or optionally, ion implantation method(s) may be used, in addition to diffusion techniques or instead of them, to achieve region-constrained doping of particular pre-defined regions on the top surface of the silicon bulk. For example, an ion source produces the desired type of ions; an accelerator unit or an acceleration grid performs acceleration of those ions to a particular level of high energy, which allows the ions to reach the target silicon or wafer or substrate and to be implanted thereon or therein at particular depth level; optionally followed by a furnace annealing process or other heat treatment process to affect the electrical properties. The ion implantation may be performed in accordance with a pre-defined pattern or map, which indicates at which locations of the target silicon or wafer will the ion implantation be performed, and which nearby locations of the target silicon or wafer will not receive ion implantation; thereby achieving selective, region-restricted or region-constrained, doping of that surface of the silicon or semiconductor wafer or substrate.

In accordance with some embodiments, P-N junction is formed only beneath the particular regions that are beneath the particular, restricted or constrained, top-side regions 12 that were treated with the dopant of the opposite polarity from the polarity of the silicon bulk. P-N junction is not formed beneath the in-between regions 13, that were not treated with that dopant.

Reference is made to FIG. 2C, which is a schematic illustration of a selectively doped surface 203 of a solar cell or PV cell, in accordance with some demonstrative embodiments. Particular regions that are denoted with “d” are the top-surface Doped regions; whereas, nearby areas that are denoted with “nd” are top-surface areas that were not doped in the selective localized doping process, and they remain with the native polarity of the doped silicon bulk. For demonstrative purposes, the doped regions are circular; however, they may have other shapes (e.g., triangle, square, rectangle, other polygon). In some embodiments, all the Locally Doped regions have the same shape; in other embodiments, the Locally Doped regions have two or more different shapes (e.g., some Locally Doped regions are circular; other Locally Doped regions of the same surface are square). In some embodiments, all the Locally Doped regions have the same size or area; in other embodiments, the Locally Doped regions have two or more different sizes or areas (e.g., some Locally Doped regions are smaller; other Locally Doped regions of the same surface are larger).

Reference is made to FIG. 2D, which is a schematic illustration of a selectively—Locally Doped surface 204 of a solar cell or PV cell, in accordance with some demonstrative embodiments. Particular regions that are denoted with “d” are Locally Doped regions; whereas, nearby areas that are denoted with “nd” are Non Locally Doped areas. A zigzag pattern or zigzag structure is used among the Locally Doped regions, as shown; other alternating patterns or structures may be used.

Reference is made to FIG. 2B, which is a schematic illustration of an upper view of the front side 200 of the solar cell, demonstrating selective “finger” contact placement only at (or on top of) constrained Locally Doped areas, in accordance with some demonstrative embodiments of the present invention. For example, a metal contact 14 is placed only on top of the P-N junction of the restricted Locally Doped area 12. A metal contact is not placed on top of the regions that are between or among the P-N junctions, or that are between or among the restricted Locally Doped areas 12.

The Applicants have realized that in some implementations, “finger” contacts or “finger” lines (e.g., which may be part of a grid having busbars and perpendicular fingers) may be prone to breaking or cutoffs, particularly if such finger lines or finger contacts are placed on a doped surface.

In accordance with some embodiments of the present invention, instead of depositing a metallization layer as fingers or as finger contacts across the entirety of the surface of the solar cell, the metallization layer is selectively and particularly placed in accordance with a pre-defined layout that matches the Locally Doped regions. For example, metallization is performed, or metallization layer is applied or added or deposited, only at the constrained regions that are Locally Doped (regions 12, or regions denoted with “d”); and metallization is not performed, or metallization layer is not applied or not added or not deposited, at the nearby regions that are Not Locally Doped (regions 13, or regions denoted with “nd” for Not Locally Doped; or regions denoted as “nf” for No Fingers). The particular shape of the metallization on the treated area may vary and is not limited, as long as it is not protruding laterally to the other side of the P-N junction, or as long as it remains constrained to the corresponding area of the P or N restricted Locally Doped areas.

Reference is made to FIG. 2E, which is a schematic illustration of intended or possible dicing lines or cutting lines or etching lines of solar cell 200, in accordance with some demonstrative embodiments of the present invention. After the solar cells 10 are ready with the selectively-restricted (constrained) Locally Doped areas 12 (or “d” regions), and the metal contacts or “fingers” 14 are placed exactly onto those Locally Doped areas, horizontal cuts 16H and vertical cuts 16V can be made on (or at, or within) the areas that are Not Locally Doped; and therefore, the resulting solar panel or PV device, or its efficiency, will be less harmed by a dicing or segmentation or grooving or trenching process.

For demonstrative purposes, and in order to avoid over-crowding of the drawing, FIG. 2E shows only some and not all of the Locally Doped and Non Locally Doped regions, and similarly shows some and not all of the metallization “fingers” placed; however, the cuts are preferably performed after the whole area of the substrate or wafer is subject to the selective, region-based, Local Doping and after the metal contacts or “fingers” have been placed onto the Locally Doped restricted areas.

For demonstrative purposes, the dicing (or segmentation) lines 16H and 16V demonstrate horizontal and vertical cutting lines or dicing lines or segmentation lines (e.g., for segmenting the solar cell into small regions); for example, in order to result in an array of generally-square or rectangular singulated (or discrete, or segmented) solar cells. However, other suitable shapes or arrangements or line orientations may be used; for example, to form triangular or hexagonal arrays or units.

In accordance with some embodiments, “blind gaps” or craters or non-transcending gaps are introduced to the semiconductor body or wafer or silicon only at the Non Locally Doped regions; and are not introduced to the semiconductor body or wafer or silicon at the Locally Doped regions; thereby producing a solar panel or PV device or solar panel that is flexible and/or rollable and/or foldable and/or that has enhanced properties of mechanical resilience, thermal resilience, mechanical shock absorption, mechanical forces dissipation, and/or mechanical durability.

### Description of Some Embodiments Related to Selective Passivation:

Some embodiments provide methods and systems for selective and/or localized treatment, and particular of passivation treatment, for PV devices or PV cells or solar panels; and further provide such PV devices or PV cells or solar panels that underwent such enhancing treatment; and particularly, further provide flexible and/or rollable and/or foldable PV devices or PV cells that underwent such enhancing treatment. The treatment(s) described herein may be performed during and/or after performing singulation operations and/or dicing operations and/or scribing operations.

Reference is made to FIG. 3A, which is a schematic illustration of a portion of a cross sectional view of a prior art Passivated Emitter and Rear Contact (PERC) or Passivated Emitter and Rear Cell (PERC) solar cell 310. It is a P-type PERC solar cell, and it includes: a P-type silicon 312 or silicon bulk at a rear side (the base region) of the solar cell (e.g., the P-type silicon bulk having a thickness of approximately 180 microns); and an N-type layer 314 at a front region (the emitter) of the solar cell (e.g., the N-type layer 314 can be formed by doping that surface of the P-type silicon 312 with an N-type dopant, such as phosphorus; to create the N-type layer 314 which may have a thickness of, for example, 0.3 to 0.5 micron; the overall thickness of the P-type silicon 312 is at least 100 or 200 or 300 times the thickness of the N-type layer 315). Front contacts 316, typically made of silver, are spread in rows on the front side; whereas on the rear side, a metal layer 318 (e.g., aluminum layer; having a thickness of 10 to 30 microns) is provided. Between the metal/aluminum layer 318 and the P-type silicon 312, there is provided a passivation layer, and preferably a dielectric layer 320; and there is a local area of the metal/aluminum layer 318 to be in contact with the P-type silicon 312. A local back surface field (BSF) 322 is provided in the P-type silicon 312 rear side, close to the metal/aluminum layer 318, and forms a high-low barrier, to prevent the electrons from the P-type silicon 312 to reach the metal semiconductor interface. The front contacts 316 are also known as “fingers” or as “finger contacts”; and between the fingers, the surface of the N-type silicon is passivated, preferably using a silicon oxide layer 324, and may be also provided with an antireflection coating. In some implementations, the front surface may have a particular texture; for example, a random collection of pyramid-like texture.

It is noted that some embodiments of the present invention may be used in conjunction with a variety of solar cells, and not only with a P-type PERC solar cell. For example, some embodiments of the present invention may be used in conjunction with an N-type PERC solar cell, a Passivated Emitter Rear Totally Diffused (PERT) solar cell, a P-type PERT solar cell, an N-type PERT solar cell, a Heterojunction with Intrinsic Thin Layer (HIT) solar cell, III-V multijunction solar cells, and/or a solar cell or PV device that combines two or more types of solar cell technologies; which may use silicon and/or other materials.

The Applicants have realized that a conventional solar cell, including the PERC solar cell 310 and other crystalline based solar cells, are typically highly fragile and/or brittle and/or breakable, and can break or become damaged upon even slight bending.

The Applicants have realized that in order to allow at least small useful level of flexibility or curvature or bending ability or flexing ability or curving ability to a solar cell or solar panel or PV device, one or more trenches or craters or grooves or “blind gaps” or non-transcending gaps can be introduced, in one or more directions throughout the solar cell or along the solar cell; for example, each such trench penetrating entirely through the metal/aluminum layer 318 and then penetrating partially (and not entirely) into the silicon layer 312 (the base region).

Reference is made to FIG. 3B, which is a schematic illustration of a portion of a cross sectional view of a PERC solar cell 302 having a trench across a part of its base region, in accordance with some demonstrative embodiments of the present invention. The PERC solar cell 302 may be generally similar in its layers structure to the PERC solar cell 310 discussed above; however, the PERC solar cell solar 302 is singulated or segmented or grooved or trenched by a trench 326 (or crater, or groove, or “blind gap”, or non-transcending gap) that is formed in the base region, which penetrates the base region layer.

In some embodiments, the trench 326 penetrates the entirety of the metal/aluminum layer 318. In other embodiments, the rear side contact (e.g., Aluminum layer) is also deposited or printed in a way that forms “streets” or rows/columns enabling the engravement or cutting to be performed directly in the silicon surface, without touching the metal containing layer (e.g., as demonstrated in other drawings).

The trench 326 then penetrates, only partially but not entirely, into the silicon 312; into a depth that is smaller than the entire thickness (or, that is smaller than the total thickness) of that silicon 312.

In some embodiments, the trench 326 penetrates into at least 50 percent and not more than 99 percent of the thickness of the silicon 312. In some embodiments, the trench 326 penetrates into at least 66 percent and not more than 99 percent of the thickness of the silicon 312. In some embodiments, the trench 326 penetrates into at least 75 percent and not more than 99 percent of the thickness of the silicon 312. In some embodiments, the trench 326 penetrates into at least 80 percent and not more than 99 percent of the thickness of the silicon 312. In some embodiments, the trench 326 penetrates into at least 90 percent and not more than 99 percent of the thickness of the silicon 312. In some embodiments, the trench 326 penetrates into at least 95 percent and not more than 99 percent of the thickness of the silicon 312. Other suitable penetration depth values, or ranges of values, may be used.

In some embodiments, the trench 326 penetrates into at least 50 percent and not more than 90 percent of the thickness of the PERC solar cell 302. In some embodiments, the trench 326 penetrates into at least 50 percent and not more than 75 percent of the thickness of the PERC solar cell 302. In some embodiments, the trench 326 penetrates into at least 60 percent and not more than 75 percent of the thickness of the PERC solar cell 302. In some embodiments, the trench 326 penetrates into at least 60 percent and not more than 67 percent of the thickness of the PERC solar cell 302. Other suitable penetration depth values, or ranges of values, may be used.

In some embodiments, the trench 326 penetrates into at least 66 percent and not more than 99 percent of the thickness of the silicon 312. In some embodiments, the trench 326 penetrates into at least 75 percent and not more than 99 percent of the thickness of the silicon 312. In some embodiments, the trench 326 penetrates into at least 80 percent and not more than 99 percent of the thickness of the silicon 312. In some embodiments, the trench 326 penetrates into at least 90 percent and not more than 99 percent of the thickness of the silicon 312. In some embodiments, the trench 326 penetrates into at least 95 percent and not more than 99 percent of the thickness of the silicon 312.

For demonstrative purposes, trench 326 is shown as a V-shaped trench or as having a triangular cross-section or a triangular profile; however, other suitable trench structures may be used; for example, trench 326 may be U-shaped, or may be shaped as a semi-sphere or a semi-circle, or may be shaped as an upside-down cone, or may be shaped as an upside-down pyramid, or may be shaped as an upside-down frustum, or may be shaped as a cylinder, or may be shaped as semi-oval, or may be generally rectangular or trapezoid, or the like.

In accordance with some embodiments, trench 326 is tapered inwardly or is tapered as it penetrates into the base region; such that the area of opening of the trench (located at the metal/aluminum layer 318) is larger than the cross-section area of the trench as it penetrates inwardly into the base region; and such that the inward ending point or ending area of the trench 326 is smaller (e.g., significantly smaller, such as ¼ or ⅓ in area size) relative to the opening of the trench 326.

In some embodiments, the distances between trenches 326, as well as their penetration depth, may be configured or selected or optimized according to several parameters or goals; including, or taking into account, the target curvature of the surface of the solar panel (or PV device) that is needed or desired in order to achieve a particular functional goal or a particular implementation. In some embodiments, the penetration depth of trench 326 is between ½ to ⅔ of the entirety of the thickness of the PERC solar cell.

In some embodiments, the penetration depth of trench 326 is configured to not exceed the P-N junction, and to remain within the base region (the silicon 312) itself, without penetrating all the way through the silicon layer 312 or the base region. In accordance with some embodiments, trench 326 and/or its edge and/or its ending, do not reach, and do not touch, and do not penetrate into, the front region (the emitter) of the PERC solar cell 302 or the N-type layer 314 of the solar cell. In other embodiments, trench 326 and/or its edge and/or its ending, may reach and/or may partially penetrate into the front region (the emitter) of the PERC solar cell 302 or the N-type layer 314 of the solar cell.

In some embodiments, the largest width of trench 326 may be in the range of 20 to 60 microns; or may be in the range of 30 to 50 microns; or may be smaller than 60 microns; or may be smaller than 50 microns; other suitable values or ranges-of-values may be used.

In some embodiments, multiple such trenches 326 are formed, across the PERC solar cell 302; and they may be spaced-apart at a fixed distance from each other, or at a varying distance from each other. In some embodiments, for example, the distance between a pair of neighboring trenches 326 may be 0.1 or 0.2 or 0.5 or 1 or 2 or 3 millimeters; or may be in the range of 0.1 to 3.0 millimeters; other suitable values or ranges-of-values may be used.

In some embodiments, trench 326 is formed or is grooved by a radiation-based process; for example, utilizing a laser beam that performs laser-based ablation; or by using a process that utilizes water or other liquid that are propelled at high-speed or as a jet of liquid that hits the lower surface of the PERC solar cell 302 and causes a groove or a trench to form therein; or by using a mechanical saw or blade or knife or cutting tool; or by using other suitable dicing or scribing or grooving or engraving mechanism; or by using chemical etching by depositing (at pre-defined locations) a particular amount of a chemical agent that causes etching; or by using a combination of two or more such processes or operations (e.g., chemical etching, followed by liquid jet).

In some embodiments, trenches 326 are preferably parallel to the “finger” contacts 316; yet in other embodiments, trenches 326 are not necessarily parallel to the “finger” contacts 316, and they can be formed in any suitable direction, or even in two or more different directions; and optionally, two trenches may even cross each other or “meet” at a unified groove or crater.

In accordance with some embodiments, due to the formation of trenches at the rear side (the base region) of PERC solar cell 302, the front region of PERC solar cell 302 is controllably breakable, or has at least a minimum desired level of flexibility, or can withstand (without breaking and without becoming damaged) at least a pre-defined level of flexing or curving or bending, or has improved resilience to mechanical shocks or mechanical forces.

In some embodiments, at least some of the trenches 326, or all of the trenches 326 of PERC solar cell 302, are maintained as “empty” trenches or grooves, and are not filled with any filler material. In other embodiments, at least some of the trenches 326, or all of the trenches 326 of PERC solar cell 302, are filled (partially, or entirely) with a filler material, or with a mixture or combination of two or more filler materials; whose functionality may be, for example, to increase mechanical resilience, to absorb or dissipate mechanical shocks or mechanical forces, to absorb or dissipate thermal changes or to increase thermal resilience, to increase the capability of the PERC solar cell 302 to withstand mechanical shocks or pressures without breaking or without being damaged, to increase the flexibility or the flexing ability of the PERC solar cell 302, or the like.

In some embodiments, trench filler material(s) may include one or more of the following materials: a polymer; a monomer; an oligomer; a resin, amorphous silicon; glass; fiber glass; carbon; a second type of silicon or semiconductor; a reactive system (e.g. monomer and photo-initiator); Ethylene-Vinyl Acetate (EVA); poly (ethylene-vinyl acetate) (PEVA); thermoplastic material; polyvinylidene fluoride (PVDF); Silicone; a homogeneous filler; a heterogeneous filler (for example, formed of a matrix material (e.g. a polymer) and an additive (e.g. discrete domains of a second, softer polymer), or the like); high-impact polystyrene (HIPS); thermoplastic elastomers (TPEs); block copolymers of polystyrene-polybutadiene and/or polystyrene-polyisoprene (diblock, triblock, multiblock, and/or other co-polymers); Polyisoprene or natural rubber; Polychloroprene or neoprene; polybutadiene; ethylene propylene diene monomer (EPDM) rubber or synthetic rubber; carbon fibers; Carbon NanoTubes (CNT); wax; metallic powder(s); nano-particles; nano-fibers; Graphene; foamed polyurethane; sponge particles; material(s) including a blowing agent (e.g., azodicarbonamide) to expand the volume of the material(s) within the trench; anisotropic material(s) or fibers or micro-fibers, being placed or deposited into the trench at a particular pre-defined direction or orientation or alignment relative to the outside surface of the solar cell (e.g., such alignment optionally being performed via an external aligning force field or external magnetic field and/or electric field and/or electro-magnetic field); isotropic material(s) or fibers or micro-fibers;

For demonstrative purposes, the discussion above may relate to a PERC solar cell in which trenches 326 are engraved or formed into the base region that is the P-type layer. However, this is only a non-limiting example, and some embodiments may similarly produce and utilize a PERC solar cell in which trenches 326 are engraved or formed in the front region/the N-type layer. instead of being formed in the base region/the P-type layer. Furthermore, some embodiments may produce and utilize a PERC solar cell in which a first set of trenches 326 are engraved or formed in the front region/the N-type layer, and also, a second set of trenches 326 are engraved or formed in the base region/the P-type layer, wherein trenches of opposite sides do not meet each other, and may be arranged in an alternating pattern or a zigzag pattern.

Reference is made to FIG. 3C, which is a schematic illustration of a portion of a cross sectional view of a PERC solar cell 303 having trenches 326 across a part of its front region, in accordance with some demonstrative embodiments of the present invention. As demonstrated, trenches 326 are engraved or formed in the front region/the N-type layer. instead of being formed in the base region/the P-type layer.

Reference is made to FIG. 3D, which is a schematic illustration of a portion of a cross sectional view of a PERC solar cell 304 in which a first set of trenches 326 are engraved or formed in the front region/the N-type layer, and also, a second set of trenches 326 are engraved or formed in the base region/the P-type layer, in accordance with some demonstrative embodiments of the present invention. Trenches 326 of opposite sides do not meet each other, and may be arranged in an alternating pattern or a zigzag pattern.

Reference is made to FIG. 3E, which is a schematic illustration of a portion of a cross sectional view of a PERC solar cell 305, having trenches across part of its base region, and further showing a possible break line 328 that extends from the end of the trench to the nearby front region or front zone, in accordance with some demonstrative embodiments of the present invention.

The Applicants have realized that in some implementations, the remaining relatively-small thickness of solar cell 305 may be brittle or fragile or may break or may splinter along the depicted breaking line 328 in response to a certain amount of bending or flexing of the solar cell 205. The Applicants have realized that such breaking or splintering, along or near the breaking line 328, may be undesired as it may reduce the efficiency of solar cell 305 in converting light into electricity; and/or as it may reduce the general mechanical resilience and mechanical durability of the entire solar cell 305.

The Applicants have realized that in some implementations, due to curving or bending or flexing of solar cell 305, and/or due to splintering along or near the depicted breaking line 328, particular areas within the base region (silicon 312) and/or within the emitter layer (layer 314) and/or at the P-N junction or interface may become directly exposed to the nearby environment, and may undergo an undesired recombination. The Applicants have realized that the ratio between (i) the exposed surface, and (ii) the bulk of these regions, increases due to the trenches that are grooved within the bulk, as well as due to possible breakage or splintering along the breaking line 328. As a result, realized the Applicants, there may be an increase in the surface recombination of the P-type layer and/or the N-type layer, and particularly at or near the P-N junction or interface, in the vicinity of (or in proximity to) the exposed surface(s). The Applicants have realized that one or more features may be used in order to prevent or reduce such possible recombination process; for example, by performing a particular treatment of the exposed surfaces and/or trenches of solar cell 305.

A first method performs the grooving of the trench through a dopant layer (e.g., a layer of boron or phosphorus), in order to facilitate and drive the doping atoms into the exposed areas of the silicon bulk. For example, the area in which the trench is to be grooved or trenched, is pre-doped with a dopant solution such that when the grooving or trenching operation is performed, the doping atoms are already present there, thereby forming a high-low barrier between the silicon bulk and the exposed surface; and the grooving or trenching operations themselves, performed via or through the dopant coating layer, may assist (in some implementations) to drive the doping atoms into or onto the exposed surfaces that are created due to such grooving or trenching. Accordingly, a first method firstly creates or adds the dopant-containing layer or coating, and then performs the trenching or grooving or cutting or segmenting operations through such dopant-containing layer or coating. In a second methods, the operations are reversed: first, the cutting or segmenting or grooving or trenching operations are performed, and then a dopant-containing layer or solution is added to the exposed surfaces of the resulting trenches or grooves or craters, and heat is applied (e.g., around 850 degrees Celsius). In a third method, localized and/or deep and/or excess P-type doping may be performed at the P-type silicon bulk, near or at the particular regions that are about to be trenched or grooves or segmented, such as via ion implantation, in order to strengthen or enhance the P-type polarity at or near such areas, and then the cutting or segmenting or grooving or trenching operations are performed. In a fourth method, two or more of the above methods may be combined or may be performed in series; for example, performing the third method (deep doping via ion implantation), and then performing the first method and/or the second method.

Reference is made to FIG. 3F, which is a schematic illustration of a cross-sectional view of a portion of a PERC solar cell 306, wherein a trench is about to be engraved at its base region (its rear side) by using a laser beam or a laser-based engraving/ablation tool (or laser blasting tool, or photo-ablation tool) that operates via a dopant layer or a dopant coating layer 330, in accordance with some demonstrative embodiments of the present invention.

PERC solar cell 306 is shown in an initial, intact, state; prior to being engraved with trenches. The rear side of PERC solar cell 306 is spread or coated with a solution of a dopant 330, or with a dopant-containing paste or solution or mixture or coating; such as a solution containing boron or phosphorous or other element that can be used as a dopant source for the appropriate exposed surface. The doping solution can be spread or deposited or applied on the rear side of the solar cell using spraying, depositing, smearing, sputtering, by utilizing a deposition unit similar to an inkjet deposition system having one or more output nozzles, by partially dipping the bottom side of the solar cell in a dopant solution, by dripping the dopant solution onto that surface, or by gluing or bonding a dopant film or a dopant-containing film or a dopant-infused film onto that surface, or by a combination of two or more such methods. The dopant solution is then dried, such as using clean air, and a layer or a coating of the dried dopant is formed. A radiation source 332, such as a laser generator or other laser source, is directed towards the area in which a trench is intended to be grooved or formed; the radiation source is activated and emits a radiation beam 34 (e.g., a laser beam) directed to the surface of the PERC solar cell 306. The beam then grooves or blasts the surface and performs ablation to thus create a trench, optionally penetrating through the metal/aluminum layer 318 (or, in some embodiments, not penetrating through the metal/aluminum layer 318 since it was net yet deposited, and will be deposited only after the grooving/trenching is performed), and penetrating into the silicon base region (layer 312), and such penetration and ablation are performed through the dried dopant layer 330 or dopant coating, such that a doped layer-surface field is formed within and/or in proximity to the outer surface(s) of the bulk silicon and/or at the panels of the trench itself; thereby preventing or reducing to efficiency losses or recombination on or near or at the trench.

Reference is made to FIG. 3G, which is a schematic illustration of a cross-sectional view of a portion of a PERC solar cell 307, wherein a trench is being engraved at its base region (its rear side) by using a laser beam or a laser-based engraving/ablation tool (or laser blasting tool, or photo-ablation tool) that operates via a dopant layer or a dopant coating layer 330, in accordance with some demonstrative embodiments of the present invention.

The laser beam 334 blasts and/or ablates the rear bulk of PERC solar cell 307, to form a trench 336 (which is generally similar in its functionality and structure to trench 326 described above). Trench 336 is formed and the dopant atoms from the dried dopant coating layer penetrate into the formed trench 336. The region denoted as zone 338, in the bulk of the base region 312 in the vicinity of the outer surface of trench 336, which is indicated between the outer surface of trench 336 and the dotted line, may be prone to recombination. However, the dopant (e.g., boron or phosphorous, depending on the type of silicon in the base region) that is present on the outer surface of the formed trench 336 and within the trench 336 itself, forms a field effect protecting layer; which prevents or reduces the recombination through passivation of the exposed surface(s), after doping.

Accordingly, a recombination-proofed PERC solar cell 307 is formed, or a reduced-recombination PERC solar cell 307 is formed. It is noted that the laser ablation process is only a non-limiting example; and some embodiments may utilize other grooving or engraving methods or tools, as long as they form the trench 336 (or 326) while also providing the dopant to its surface and/or vicinity.

Reference is made to FIG. 3H, which is a schematic illustration of a resulting PERC solar cell 308, having a trench 336 in the back region (rear surface), wherein the trench 336 was engraved or formed after surface doping, in accordance with some demonstrative embodiments of the present invention. In PERC solar cell 308, the exposed surfaces 340 of the trench 336 itself, as well as the region of breaking line 328 in the front region of PERC solar cell 308, that were regularly prone to possible recombination, are now recombination-proofed or are now configured to undergo reduced recombination. To prevent the recombination process, after the trench 336 is grooved, a field effect protection layer 342 is formed through the exposed surface(s), by spraying or depositing or spreading or dripping there a doping solution or a dopant-containing agent or solution, followed by a high temperature drive-in process. The field effect protection layer 342 prevents the recombination process within at the exposed surface of the P-type region (layer 312) and the N-type region (layer 314). Other suitable treatments may be performed on the exposed surfaces of PERC solar cell 308 and/or its trench(es) 326; for example, gas treatment, heat treatment (annealing), hydrogen treatment, or a combination of two or more treatments.

In accordance with some embodiments, one or more methods or processes may be used to create and/or activate a passivation layer, particularly at (or near, or along) the exposed surfaces of the trenches (or grooves). In some embodiments, a chemical process may be used, which may utilize Chemical Vapor Deposition (CVD), Physical Vapor Deposition (PVD), Atomic Layer Deposition (ALD), Plasma Enhanced Chemical Vapor Deposition (PECVD), sputtering or sputter film deposition, Thermal Evaporation Deposition, or other methods for depositing or spraying of (or coating with) a physical barrier material (e.g., dopant-free materials such as silicon oxide or dielectric materials); for example, by covering the exposed surfaces of the trenches with a dielectric material (e.g., a coating layer having thickness of 2 to 15 nanometers; wherein the depth of each trench is in the range of 60 to 150 microns, or 60 to 120 microns).

In some embodiments, a chemical process may be performed, to cover or coat the exposed surfaces of the trenches with a dielectric material; and then, doping or excess doping (followed by heating/annealing) may be performed at the surfaces of the trenches to also create a potential barrier and to obtain field-effect protection. Optionally, chemical passivation may be performed after the grooving or trenching operations, using a suitable dielectric material (e.g., silicon dioxide; aluminum trioxide; titanium dioxide) followed by moderate heating (e.g., around 250 degrees Celsius).

In other embodiments, a field-effect protection layer or a potential based protection layer may be performed, by performing excessive doping or excess doping or additional doping of the exposed surfaces of the trenches, in order to obtain a potential barrier or field-effect based protection; for example, by depositing a dopant or a dopant-containing layer or solution or vapor, and by then heating or annealing (e.g., at 400 degrees Celsius, for 30 to 60 minutes).

In some embodiments, the field-effect protection layer is formed by cutting through a dopant layer or a dopant coating layer; or by performing laser ablation prior to cutting or grooving or trenching (e.g., accompanied or followed by high-temperature heating, such as around 850 degrees Celsius); or by performing laser ablation subsequent to cutting or trenching or grooving (e.g., accompanied or followed by moderate-temperature heating, such as around 450 degrees Celsius).

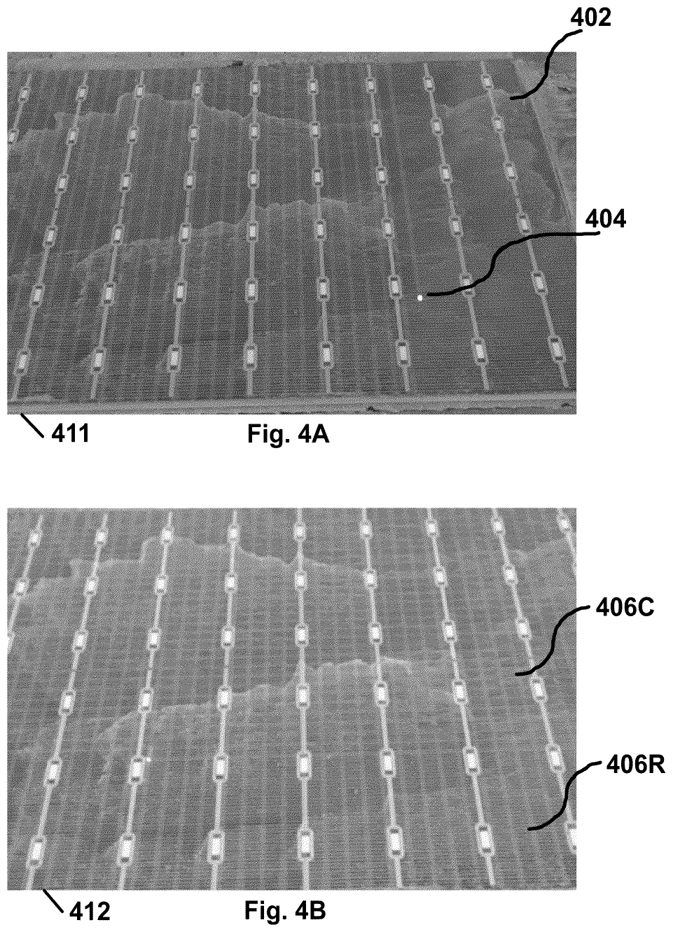

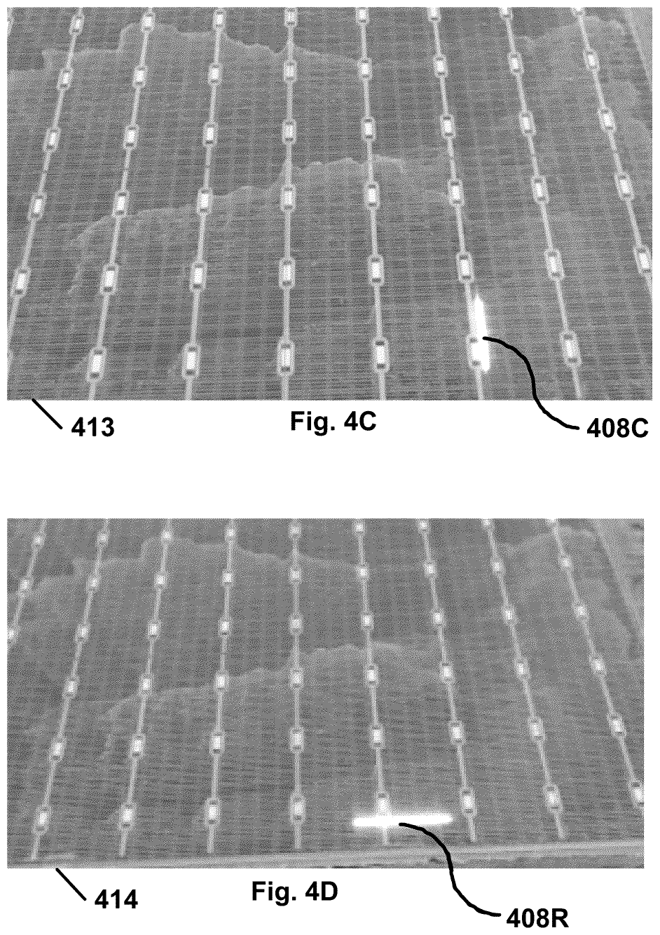

Reference is made to FIGS. 4A to 4D, which are photographs 411 to 414 (respectively) demonstrating stages in the process of treating a PERC solar cell 400 (e.g., prior to performing dicing operations), in accordance with some demonstrative embodiments of the present invention.

FIG. 4A shows the PERC solar cell 400, onto which a dopant solution (e.g., containing boron atoms) is spread and dries. A boron-enriched layer 402 (or a boron-doped layer, or a boron-infused layer, or a boron-coated layer, or a boron-enhanced layer) is thus formed on top of the top surface of PERC solar cell 400. In some embodiments, layer 402 may be a phosphorus-enriched layer (or a phosphorus-doped layer, or a phosphorus-infused layer, or a phosphorus-coated layer, or a phosphorus-enhanced layer), or may be other type of doped layer or dopant-enriched layer (or doped layer, or a dopant-infused layer, or a dopant-coated layer, or a dopant-enhanced layer). A laser beam moves in accordance with a pre-defined pattern, such as along rows and then along columns, across the surface of PERC solar cell 400. For demonstrative purposes, a white dot 404 denotes a point at which the laser beam touches the PERC solar cell 400; the size of shite dot 404 is intentionally exaggerated in the drawing, and is depicted at about 3 to 5 times its actual size, in order to make the white dot visible in the drawing.

As demonstrated in FIG. 4B, the laser beam may move along parallel rows 406R and then along parallel columns 406, or vice versa; or may move in accordance with other pre-defined pattern; in order to selectively and locally heat the particular treated points or lines or areas, and to drive the boron (or the phosphorus, or other dopant) into the silicon bulk at (or near) those treated points or lines or areas.

As demonstrated in FIGS. 4C and 4D, once the heating process ends, an ablating laser beam is moved or is transferred substantially in the middle of the heated columns 106C and the heated rows 106R, respectively, at locations 108C and 108R; in order to dice the PERC solar cell 400.

It is noted that other suitable methods may be used, instead of laser-based heating, or in addition to laser-based heating, for driving the dopant into the bulk silicon at the vicinity of the surface of the diced regions; for example, using an ion implantation or atom implantation process that utilizes an acceleration grid, or using a particular chemical reaction that causes dopant implantation or dopant fusion or dopant transfer, or other suitable methods.

Some embodiments may utilize other and/or additional methods for preventing or reducing the recombination within the bulk base region that is being exposed due to the cutting process; for example, by doping the exposed surface after the trench is formed.

Some embodiments may provide methods and systems for treating exposed solar cell surfaces or regions, during and/or after performance of dicing operations and/or grooving through silicon layer(s). For example, dicing operations may be performed through a dopant-containing layer or through a dopant coating layer, after the dopant has been placed (or deposited, or was applied as a coating) adjacent to the diced areas or regions (or at the intended dicing lines). According to some embodiments, the doping may be performed selectively and locally in the particular places or regions or lines (or dicing lines) that were diced, immediately after the dicing action was performed. Such methods may prevent or reduce recombination in the diced areas, or along or near the dicing lines, and/or on the exposed surface while passivation takes place.

Some embodiments provide a singulated or segmented solar cell or PV cell, having a base region and an emitter layer; wherein the singulated or segmented solar cell or PV cell has a plurality of trenches engraved in a portion of a bulk silicon of the base region; wherein exposed surfaces of each trench are doped (e.g., with boron or phosphorus or other dopant) in order to prevent or reduce recombination in the vicinity of the exposed surfaces of the trenches.

Some embodiments provide a method for treating a solar cell, to prevent or reduce recombination in a bulk silicon of the solar cell that is adjacent to exposed surfaces due to their exposure. The method may include: spreading or depositing or applying a dopant solution (or a dopant paste, or other dopant-containing material) onto a surface that is intended to be singulated or segmented or trenched or grooved through the solar cell; drying the dopant solution or dopant material, on the solar cell, such that a dopant layer is formed on the solar cell; selectively and/or locally heating particular areas or regions or lines that are intended to be singulated or segmented or grooved or trenched; and then, singulating or segmented or grooving or trenching the solar cells at the areas or regions or lines that were heated.

Some embodiments provide a method of treating a solar cell to prevent or reduce recombination in a bulk silicon in the vicinity of the surface of the solar cell that would be exposed due to being singulated. The method may include: singulating the solar cell so that exposed surfaces are formed; and then, forming a protection layer (e.g., a dopant-containing layer or coating) on the exposed surfaces. In some embodiments, the protection layer may be formed using a surface treatment selected from a group consisting of: solution doping, gas doping, annealing, hydrogen treatment.

### Description of Some Embodiments Related to Metallization Layout:

Some embodiments provide solar cells and PV cells having an innovative metallization layout or metallization structure or metallization configuration; as well as methods and systems for producing such solar cells and PV cells.

Some embodiments provide an innovative architecture or structure for solar cells or PV cells, having a metallization layout that may accord or may accommodate different functional applications or functionalities, and may be particularly suitable for solar cells that are configured to be diced and singulated or segmented or trenched or grooved, or that are configured to form thin, flexible and/or rollable and/or foldable solar cell that have non-transcending craters or “blind gaps” that provide such flexibility capability as well as mechanical shock absorption and dissipation properties.

Some embodiments further provide a solar cell or PV cell in which distinct electrical contacts are associated with distinct and restricted (or constrained, or localized) doped areas. Such solar cells systems can be used for various applications, such as for sensors that are based on a pixelated substrate, or flexible or rollable or foldable solar cells that can be used for various purposes.

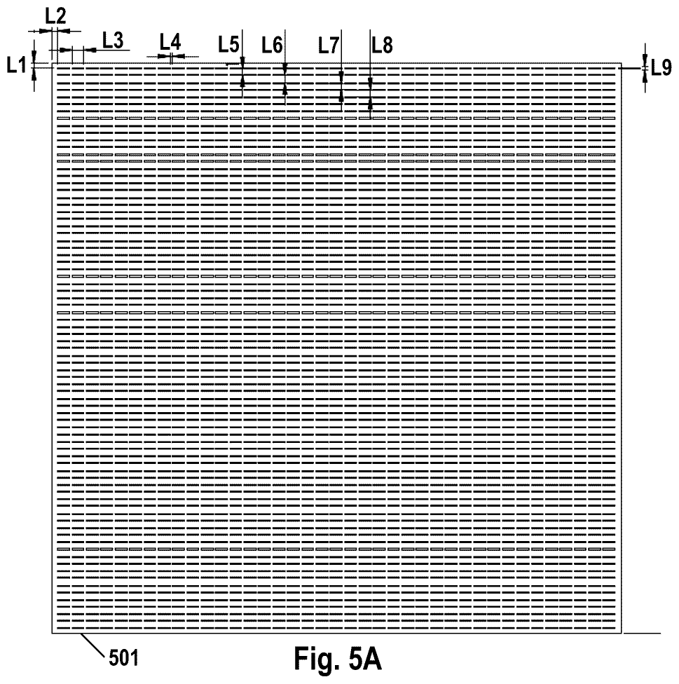

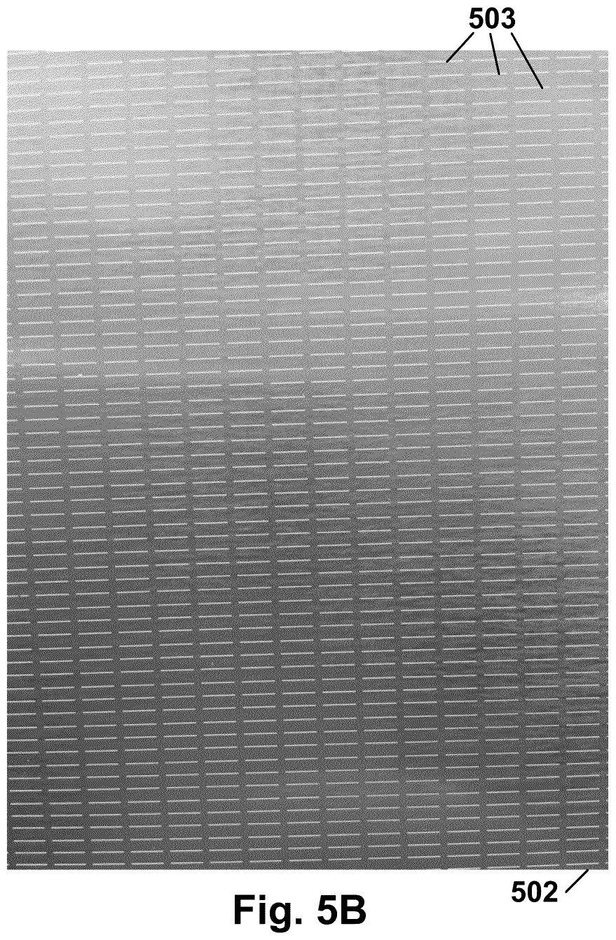

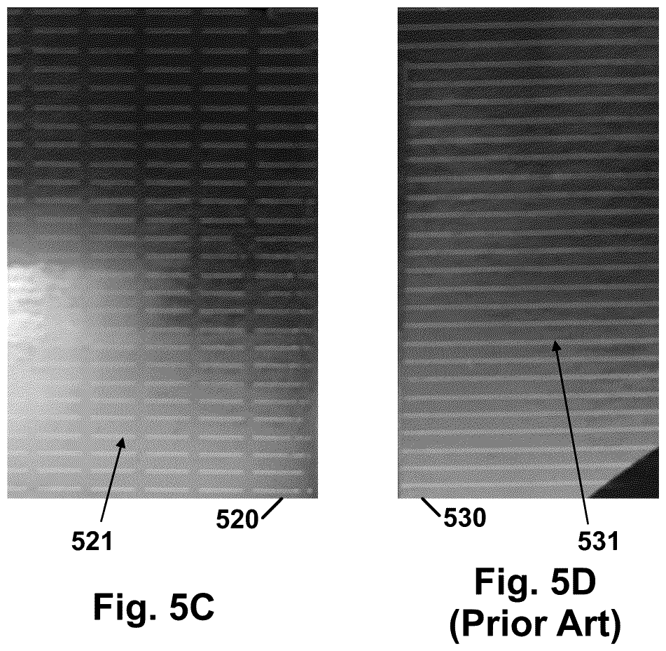

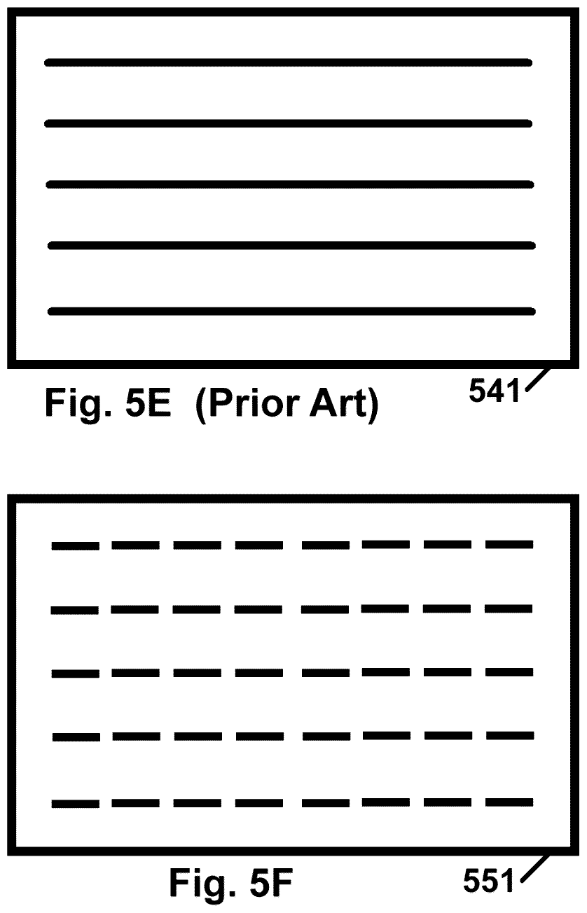

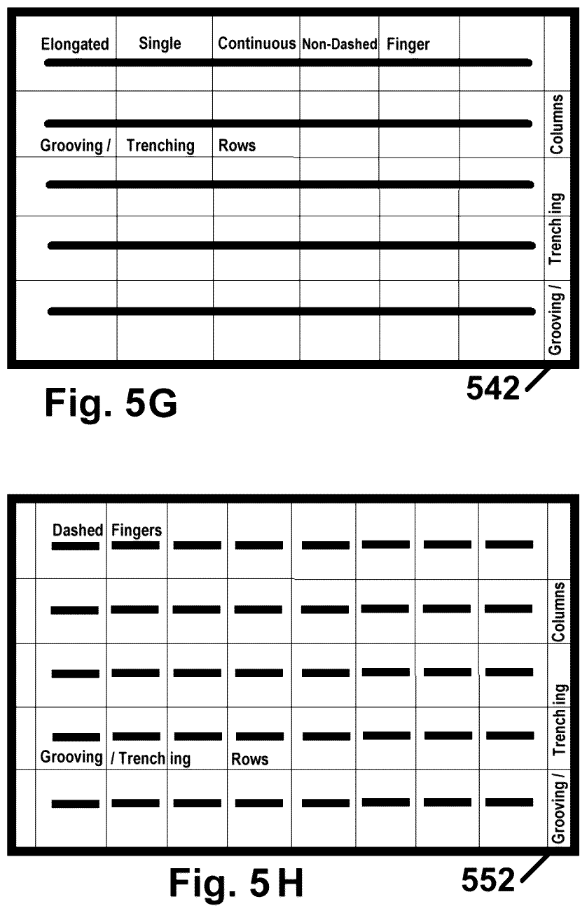

Reference is made to FIG. 5A, which is a schematic illustration of a plan 501 of electrical contacts metallization layout for a solar cell, in accordance with some demonstrative embodiments. Instead of producing and having elongated “finger” contacts (which were used in conventional/prior art solar cells), plan 501 provides lines of the metal contact material that are selectively sized (and placed, and positioned) to fit particular needs of a certain application or functionality.

For example, a generally-rectangular or generally square shaped solar cell is shown in layout plan 401.

Distance L1 indicates the vertical distance between (i) the first row of contacts and (ii) the nearest horizontal edge of the solar cell. For example, distance L1 may be 1.375 millimeter.

Distance L2 indicates the horizontal distance between (i) the left-most point of the left-most electrical contact, and (ii) the nearest vertical edge of the solar cell. For example, distance L2 may be 1.725 millimeter.

Distance L3 indicates the horizontal length of a horizontal electrical contact. For example, distance L3 may be 3.3 millimeter. For example, distance L3 may be approximately two times the distance L2; or, distance L3 may be approximately 2 or 2.5 times the distance L1.

Distance L4 indicates the horizontal distance or the horizontal gap, between a pair of two neighboring electrical contacts in the same row. For example, distance L4 may be 0.70 millimeter. For example, distance L4 may be approximately 20 or 25 percent of distance L3; such that the horizontal gap between two electrical contacts, is approximately in the range of 10 to 25 percent of a horizontal length of a single electrical contact.

Distances L5, L6, L7 and L8 indicate the vertical distance or the vertical gap, between a pair of two neighboring and generally-parallel electrical contacts, located in two neighboring rows of electrical contacts. For example, distance L5 is 0.560 millimeter; distance L6 is 1.88 millimeter; distance L7 is 1.56 millimeter; and distance L8 is 1.88 millimeter. As demonstrated, distance L5 and distance L6 and distance L7 have values that are different from each other, to provide non-fixed or non-uniform gaps or distances among neighboring rows of electrical contacts, to thereby accommodate a particular functional goal. As also demonstrated, distance L6 is equal to distance L8, demonstrating that some pairs of neighboring rows of electrical contacts may have the same distance within each pair, to accommodate a particular functional goal. Accordingly, the vertical gap among rows of contacts may be generally non-fixed or non-uniform; yet it is possible that two different pairs of electrical contacts would have the same value of vertical gap between their two rows.

Distance L9 indicates the thickness of an electrical contact that outputs electric power (voltage or current) from the solar cell. For example, distance L9 may be 28 microns.

Reference is made to FIG. 5B, which is a photograph of an upper-side view of a solar cell 502 after placement of the metallization layout of electrical contacts, in accordance with some demonstrative embodiments; for example, according to layout plan 501 or according to other suitable layout plan. The rows of metallization contacts 503 can be seen, in accordance with the planned layout. A single solar cell 502, which may be (for example) approximately 20 by 20 centimeters, may have hundreds or even thousands of such contacts 503, arranged in generally-parallel rows.

Reference is made to FIG. 5C, which is a photograph of a portion of a solar cell 520 in accordance with some embodiments of the present invention; showing a set of discrete, spaced-apart, segmented or dashed, metallization “fingers” or electrical contacts 521 arranged in generally-parallel rows. It is shown side by side with FIG. 5D, which is a photograph of a portion of a prior art solar cell 530, in which electrical contacts 531 or metallization “fingers” are continuous rows; such that each “finger” is a full, elongated, continuous line or wire of electrical contact; and wherein there is exactly one finger, and not a plurality of spaced-apart/segmented/dashed fingers, in each row.

Reference is made to FIG. 5E, which is a schematic illustration of a prior art solar cell 541, in which electrical contacts or metallization “fingers” are configured as continuous rows; such that each “finger” is a full, elongated, continuous line or wire of electrical contact; and wherein there is exactly one finger, and not a plurality of spaced-apart/segmented/dashed fingers, in each row. For example, there are a total of 5 electrical contacts or metallization “fingers” in the prior art solar cell 541 shown in FIG. 5E.

Reference is made to FIG. 5F, which is a schematic illustration of a solar cell 551 in accordance with some embodiments of the present invention; showing a set of discrete, spaced-apart, segmented or dashed, metallization “fingers” or electrical contacts arranged in generally-parallel rows.

For example, in the same area, the prior art solar cell 541 has a total of 5 elongated electrical contacts or metallization “fingers”, each such elongated finger extending across an entirety of the total width of the prior art solar cell 541 (optionally not covering a small region at the margin or border of the solar cell 541). In contrast, in the same area, the innovative solar cell 551 has a total of 40 discrete electrical contacts or metallization “fingers”, arranged in 5 rows, each row having 8 discrete or parallel or segmented electrical contacts or metallization “fingers”.

The Applicants have realized that the innovative, dashed or segmented, metallization layout or electrical “fingers” arrangement, may provide one or more functional benefits or advantages, over the prior art approach or elongated, non-segmented, non-dashed, “finger” contacts. For example, the innovative layout may contribute to the mechanical capability of the solar cell to flex or to curve or to bend or to be rolled, without causing mechanical breakage and/or functional damage to the “fingers” themselves and/or to the solar cell in its entirety. Additionally or alternatively, the innovative layout of the segmented/dashed metallization “fingers” may, by itself, increase the flexibility or the rolling capability or the bending capability of the solar cell in its entirety. Additionally or alternatively, the innovative layout of the segmented/dashed metallization “fingers”, by itself, may increase the structural resilience and/or durability of the solar cell, and/or may increase the mechanical resilience and/or durability of the solar cell, and/or may increase the capability of the solar cell to absorb and/or to dissipate and/or to withstand mechanical forces and/or mechanical shocks, and/or may increase the capability of the solar cell to absorb and/or to dissipate and/or to withstand thermal changes or thermal forces.

Furthermore, the innovative layout of the segmented/dashed metallization “fingers” or electrical contacts, may provide particular benefits and/or advantages once the solar cell is intended to be singulated or segmented or diced or trenched or grooved; or once trenches or grooves or craters or non-transcending gaps or “blind gaps” are formed within a substrate body or a semiconductor body or a silicon layer or a semiconductor wafer of the solar cell in order to enhance its capability to flex or curve or roll or bend. Particularly, the innovative layout of the segmented/dashed metallization “fingers” or electrical contacts, may enable to perform such dicing or singulation, or such formation of trenches or grooves or craters or non-transcending gaps or “blind gaps”, exactly along Trenching Rows (or Grooving Rows, or Singulation Rows, or Dicing Rows) that are between parallel rows of the segmented/dashed metallization “fingers” or electrical contacts, and exactly along Trenching Columns (or Grooving Columns, or Singulation Columns, or Dicing Columns) that traverse exactly through the gaps that innovatively exist between each pair of neighboring metallization “fingers” or electrical contacts of the same row.

Reference is made to FIG. 5G, which is a schematic illustration demonstrating how applying of Trenching/Grooving (or Segmenting) rows and columns would affect a prior art solar cell 542, in which each row has a single, elongated, non-dashed, non-segmented, electrical contact or metallization “finger”. The thin lines indicate possible Trenching/Grooving rows and columns. The Trenching/Grooving rows may be located between pairs of neighboring elongated fingers; however, the Trenching/Grooving columns would slice through or traverse through the elongated fingers, thereby possibly damaging the mechanical and/or functional properties of those elongated fingers, and/or thereby possibly damaging the mechanical resilience and/or the flexing capability of the entire solar cell.

Reference is made to FIG. 5H, which is a schematic illustration demonstrating the innovative utilization of Trenching/Grooving rows and columns on an innovative solar cell 552, in which each row has multiple, discrete or dashed or segmented or spaced-apart or non-continuous, electrical contacts or metallization “fingers”, in accordance with some demonstrative embodiments of the present invention. The thin lines indicate possible Trenching/Grooving rows and columns. The Trenching/Grooving rows may be located between pairs of neighboring elongated fingers; and innovatively, the Trenching/Grooving columns do not slice through and do not traverse through, and do not interfere with, any electrical contact or any metallization finger; as the Trenching/Grooving columns pass exactly through (or at) the non-metallized horizontal gap that separates each two neighboring yet spaced-apart dashes (or segments) of electrical contacts, or passes through those particular gaps that are intentionally non-metallized and not covered by an electrical contact or “finger”. This innovative layout and structure prevent or reduce possible damage to the mechanical and/or functional properties of the electrical contacts or fingers, and/or maintains and/or improves the mechanical resilience and/or the flexing capability of the entire solar cell.

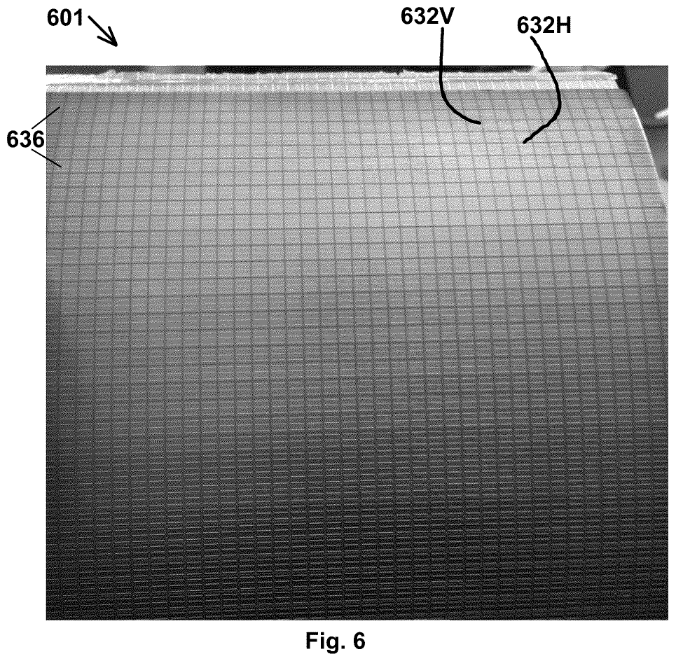

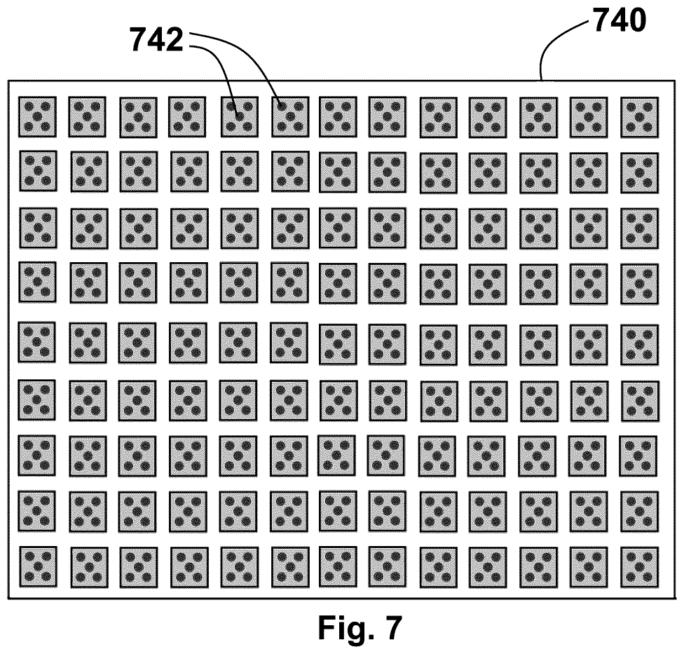

Reference is made to FIG. 6, which is a photograph of a flexible solar cell 601 with the innovative metallization layout, after singulation (or segmentation, or grooving, or trenching), of the solar cell into segments, in accordance with some demonstrative embodiments of the present invention. As described, one of the functional goals of the dashed, segmented, non-continuous, electrical contacts or metallization fingers, is to enable production of a flexible solar cell having grooves (or groove lines, or trenches, or trenching lines) that contribute to its capability to flex or bend or curve without breaking and/or without causing functional damage to the solar cell. Solar cell 601 is diced (or grooved, or trenched) in trenches (or grooves) along vertical trenching/grooving lines 632V and horizontal trenching/grooving lines 632H; such that the solar cell becomes flexible (and/or rollable, and/or foldable) and can be flexed or folded or rolled or curved, along both directions (both horizontally and vertically) without becoming mechanically broken or functionally damaged. For demonstrative purposes, solar cell 601 is shown as being curved or flexed or bent along the horizontal trenches; however, this is a non-limiting example, and this solar cell 601 can similarly be curved or flexed or bent along the vertical trenches. Other suitable directions may be used; for example, using two (or more) sets of intersecting lines, wherein lines in each set are generally parallel to each other.

The horizontal trenches or grooves are formed exactly along the horizontal trenching/grooving lines 632H; each such line going exactly between two adjacent horizontal fingers or metallization contacts. Due to the innovative metallization layout, the vertical trenches or grooves are formed exactly along the vertical trenching/grooving lines 632V, passing exactly through gaps that separate the discrete, segmented, dashes of metallization contacts or fingers 636. In this way, singulating or segmenting or grooving or trenching the solar cell to segments, does not damage the metallization contacts or any fingers, and does not damage at all (or, in some implementations, does not significantly damage) the electric performance of the underlying silicon layers, and prevents a reduction in the efficiency of the solar cell to convert light into electric power.

Reference is now made again to FIG. 2E, which demonstrates the relevant grooving/trenching lines (or dicing lines, or segmentation lines), which may be used for producing a flexible, mechanically resilient, mechanical shock absorbing, solar cell or solar panel, in accordance with some demonstrative embodiments of the present invention.

For example, selectively-doped regions 12 that are Locally Doped with the opposite polarity (or regions denoted with “d” for Locally Doped) are regions that are covered with a dopant or a doping agent (e.g., boron or phosphorus), and the dopant atoms are driven-in into the silicon or substrate and formed a doped layer; whereas non Locally Doped regions 13 (or regions denoted with “nd”) are not Locally Doped. The solar cell 200 is ready with the selectively restricted Locally Doped areas 12, the metallization contacts 14 are placed exactly onto those Locally Doped 12, in a segmented manner, each dashed or segmented contact being within each Locally Doped region; thus preventing electrical shorting between the Locally Doped regions and the nearby regions that were not Locally Doped. Trenches are formed made on areas that are neither Locally Doped nor metallized, neither covered with a dopant for Locally Doped nor covered with a metal contact or finger, along the trenching lines 16H (horizontal) and 16V (vertical); and therefore, the electrical performance is not harmed at all (or, is not significantly harmed) by the trenching or grooving or dicing or segmentation operations.

Reference is made to FIG. 7, which is a schematic illustration of a rear side of a solar cell, having a metallization layout that is intended to enable formation of a flexible and mechanically resilient PERC solar cell 740, in accordance with some demonstrative embodiments of the present invention.

For example, the rear side of the PERC solar cell 740 is covered or coated with a dielectric coating layer, which has particularly-placed apertures or holes or openings 742. Those selectively-placed openings 742 in the dielectric coating layer enable the formation of good ohmic contact with the silicon bulk of the solar cell 740 that is immediate beneath (or immediately adjacent to) the dielectric layer. In this way, the metal (e.g., aluminum) that forms the electric contacts or “fingers”, such as in the form of aluminum paste or metal paste, can enter through those openings 742 and can then harden or cure and become structured electrical contacts precisely at those openings. It is noted that aluminum is a non-limiting example; as aluminum can be diffused through the silicon to create an aluminum alloy next to the aluminum bulk that ensures ohmic contact; although other processes for producing ohmic contacts to the metallization fingers may also be used in some implementations. It is also noted that in order to not over-crowd the drawing, not all the selectively Locally Doped region are shown, and not all the electric contacts or “fingers” are shown; and the trenches or grooved are preferably made after the whole area of the substrate is selectively Locally Doped (using the localized, region-based, selective Locally Doped pattern) and after the metal contacts or “fingers” are placed onto the selectively Locally Doped constrained regions.

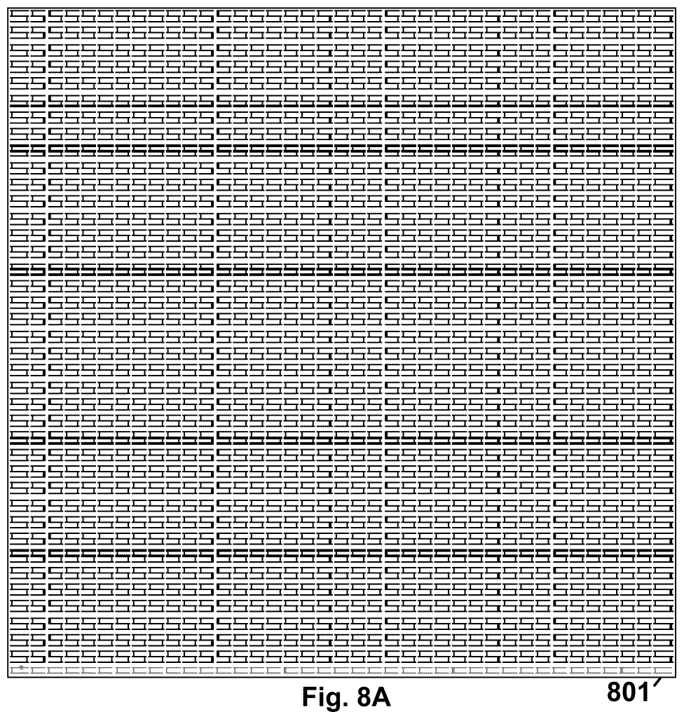

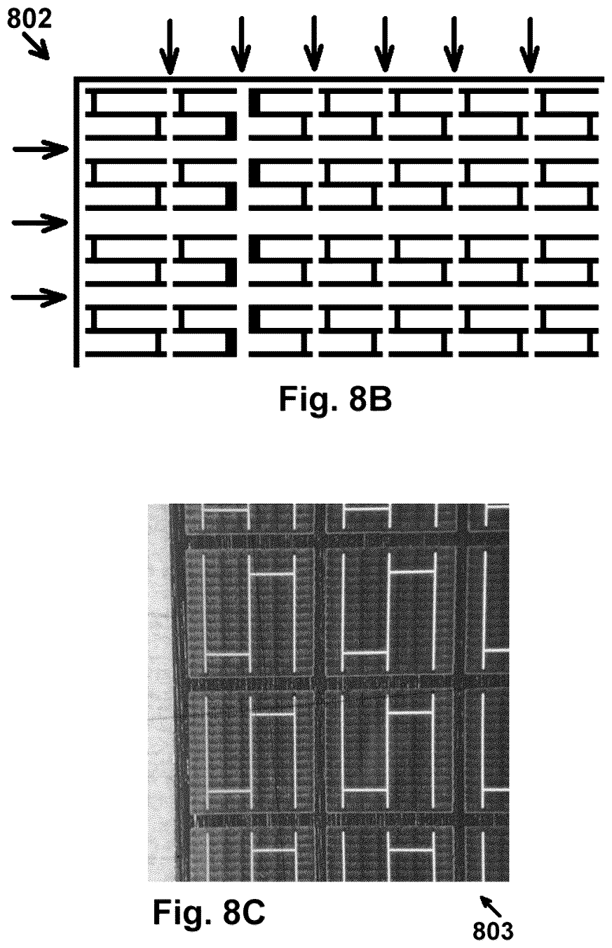

Reference is made to FIG. 8A, which is a schematic illustration of another layout plan 801 for contacts metallization for another solar cell, in accordance with some demonstrative embodiments of the present invention. Reference is also made to FIG. 8B, which is an enlarged (or zoomed-in) view of a portion 802 of the layout plan 801, to more clearly show its details and structure, in accordance with some demonstrative embodiments of the present invention. Reference is also made to FIG. 8C, which is a photograph of a portion 803 of the layout plan 801 of a flexible solar panel, in accordance with some demonstrative embodiments of the present invention. The electrical “finger” contacts, or the metallization contacts, are not structured as straight lines or dashes; but rather, they are Z-shaped or S-shaped or zigzag shaped or have a serpentine shape, while still being discrete and spaced-apart metallized contacts; to thereby increase the possible points (or lines, or areas) of electrical contact between those contacts and wires of the solar cell. FIG. 8C further demonstrates the Locally Doped regions on the top surface, with narrow or thin rows/columns or “streets” among them that were not treated with local doping, and that are suitable for performing there precise cutting or grooving or trenching or segmentation.

Six vertical arrows are pointing to indicate the small, yet functional, horizontal gaps between each pair of adjacent columns of Z-shaped contacts; and precisely along the vertical lines that extend from each of these vertical arrows, vertical segmentation/grooving/trenching operations may be performed, exactly between those Z-shaped contacts and without touching or traversing each such Z-shaped contact.

Similarly, three horizontal arrows are pointing to indicate the small, yet functional, vertical gaps between pair of adjacent rows of Z-shaped contacts; and precisely along the horizontal lines that extend from each of these horizontal arrows, horizontal segmentation/grooving/trenching operations may be performed, exactly between those Z-shaped contacts and without touching or traversing each such Z-shaped contact.

The depicted structure and shapes, as shown in FIGS. 8A and 8B, are only non-limiting examples; and other suitable structures may be used for such electrical contacts, for example, M-shaped, W-shaped, U-shaped, V-shaped, O-shaped, H-shaped, 5-shaped, star-shaped, asterisk shaped, a combination of two or more shapes, or the like.

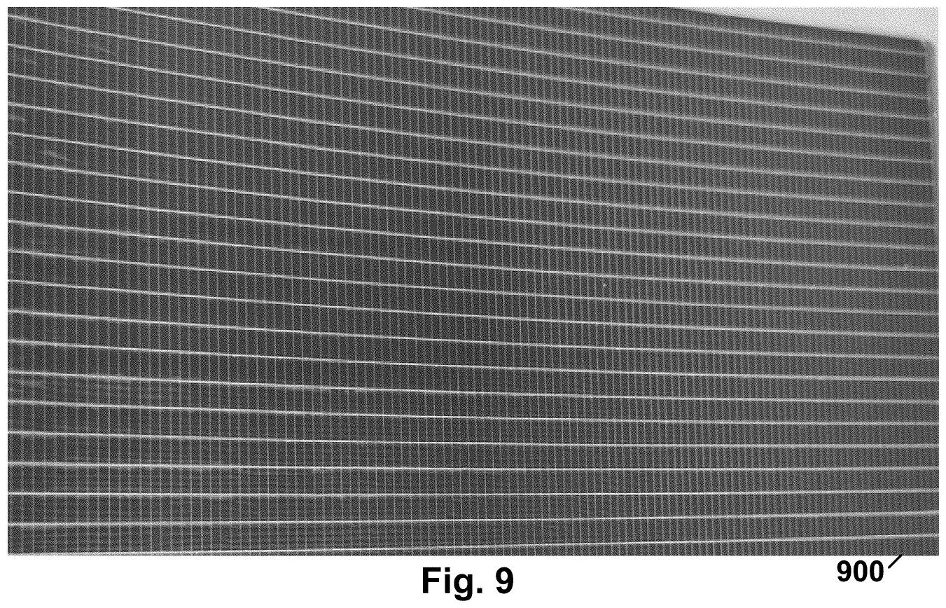

Reference is made to FIG. 9, which is a photograph of a flexible solar cell 900 demonstrating metallization contacts or “fingers”, as well as wires, in accordance with some demonstrative embodiments. It demonstrates metallization contacts or “fingers”, which may be implemented as horizontal dashed segments; and further demonstrating wires of the solar cell, which may be horizontal and/or vertical.

Some embodiments provide a solar cell or a PV cell having metallization contacts layout in accordance with a distinct pattern or a pre-defined arrangement; particularly, each two contacts are spaced apart, and each row of spaced-apart contacts is also spaced-apart from adjacent (neighboring) rows of spaced-apart contacts. In some embodiments, each discrete contact is a dashed or segmented line or linear wire, that is less than 10 percent of the length (or the width) of the solar cell (or PV cell). In some embodiments, the structure of each such contact is non-linear, or may be U-shaped, V-shaped, 5-shaped, O-shaped, X-shaped, S-shaped, M-shaped, W-shaped, H-shaped, star-shaped, asterisk shaped, or may have other shape or a combination of two or more such shapes.

Some embodiments provide methods of producing a solar cell, by laying or forming or adding the metallization contact layout as described above in order to accord or to accommodate a process of solar cell singulation or segmentation or trenching or grooving.

In some embodiments, a solar cell has pre-defined and particularly-placed openings in a dielectric coating layer that covers a rear side or a rear surface of the solar cell; wherein metal paste (e.g., aluminum paste or aluminum-based alloy) is deposited or added or enters through such openings and then hardens or cures or solidifies to form such electric contacts.

Some embodiments provide a solar cell or PV cell, that is singulated or segmented or trenched or grooved according to a pre-determined pattern of segmentation regions, to increase flexibility and/or mechanical resilience of the solar cell; wherein each singulated area or segmented region of the solar cell is provided with metal wires that connect the singulated area or the segmented region in intimate physical and electrical contact with at least one location of a metallization pattern that is provided on each of the singulated areas ore segmented regions.

In some embodiments, the metallization pattern in each singulated area or segmented region is a pattern selected from a group of geometrical layouts consisting of: Z-shaped, S-shaped, O-shaped, W-shaped, M-shaped, X-shaped, H-shaped, V-shaped, U-shaped, star-shaped, asterisk shaped, and a combination of two or more such shapes; wherein the metallization pattern enables at least one point-of-contact between the wires and each respective metallization contact.

Some embodiments provide a flexible Photovoltaic (PV) cell, comprising: a semiconductor body (e.g., silicon bulk), having a base region and a front region; wherein the base region is P-type silicon; wherein the front region is P-type silicon having constrained and pre-defined regions that are N-type silicon.

In some embodiments, the base region is native P-type silicon, such as, a silicon bulk that was entirely doped with boron or with a P-type dopant; wherein the pre-defined regions that are N-type silicon, in the front region, are pre-defined regions of that bulk silicon (i) that were initially doped with boron to become P-type regions as part of the P-type silicon bulk, and (ii) that subsequently were doped with phosphorus to become N-type regions that are scattered among P-type regions that surround them or that are neighboring them (e.g., co-located near them at the same plane or depth, in the front region of the silicon bulk). The particular and pre-defined and constrained N-type regions are only in the front region of the silicon bulk, and are not in the base region of the silicon bulk.

In some embodiments, the base region has non-transcending trenches that penetrate into between 50 to 99 percent (or, between 66 to 99 percent; or, between 75 to 99 percent; or, between 50 to 95 percent; or, between 66 to 95 percent; or, between 75 to 95 percent; or, less than 99.5 percent) of a total thickness of the base region, and that do not penetrate into an entirety of the total thickness of the base region; wherein said non-transcending trenches in the base region increase flexibility and mechanical resilience and mechanical shock absorption of flexible said PV cell.

In some embodiments, the base region has non-transcending trenches that penetrate into between 50 to 99 percent (or, between 66 to 99 percent; or, between 75 to 99 percent; or, between 50 to 95 percent; or, between 66 to 95 percent; or, between 75 to 95 percent; or, less than 99.5 percent) of a total thickness of the semiconductor body, and that do not penetrate into an entirety of the total thickness of the semiconductor body; wherein said non-transcending trenches in the base region increase flexibility and mechanical resilience and mechanical shock absorption of flexible said PV cell.

In some embodiments, at least some of said non-transcending trenches contain a filler material having mechanical force absorption properties, which provides mechanical shock absorption properties to said flexible PV cell.

In some embodiments, the flexible PV cell is a Passivated Emitter and Rear Contact (PERC) PV cell; wherein the base region is a P-type silicon having a particular thickness in a range of 100 to 250 microns; wherein the front region is a silicon layer, having a thickness in a range of 0.3 to 0.5 microns, and comprises said N-type silicon regions that are scattered among P-type silicon regions that are co-located at a same plane as the N-type silicon regions.

In some embodiments, each trench is tapered inwardly and is generally V-shaped or U-shaped.

In some embodiments, a width value of the widest opening of each trench is in a range of 30 to 50 microns. In some embodiments, am average width value of each trench is in a range of 30 to 50 microns. In some embodiments, a maximum width value of each trench is in a range of 30 to 50 microns.

In some embodiments, exposed surfaces of each trench are doped with boron or phosphorus to reduce recombination at, or in proximity to, said exposed surfaces. In some embodiments, exposed surfaces of each trench are doped with phosphorus to reduce recombination at, or in proximity to, said exposed surfaces. In some embodiments, exposed surfaces of each trench are doped with boron to reduce recombination at, or in proximity to, said exposed surfaces.

In some embodiments, the front region, which comprises said pre-defined N-type silicon regions, also has a set of additional trenches, that penetrate inwardly through an entirety of a depth of the N-type regions and further penetrate into some, but not all, of the thickness of the P-type base region; wherein trenches that penetrate downwardly into the pre-defined N-type silicon regions, do not meet with trenches that penetrate upwardly into the P-type silicon layer.

In some embodiments, at least some of the trenches that penetrate into the front region that comprises said pre-defined N-type silicon regions, contain a trench filler material that is configured to increase mechanical resilience and mechanical forces absorption properties of said PV cell.

In some embodiments, discrete, metallized, electrical finger contacts are located exactly on top of said pre-defined N-type silicon regions of the front region, and are not located on top of P-type silicon bulk that surrounds each of the pre-defined N-type silicon regions of the front regions.

In some embodiments, the front region is covered by a pre-defined pattern of discrete, metallized, electrical finger contacts, which comprises: generally parallel rows of discrete, metallized, electrical finger contacts; wherein each pair of two adjacent rows of electrical finger contacts, are spaced-apart by a row of non-metallized surface region; wherein each pair of two adjacent electrical finger contacts, are spaced-apart by a column of non-metallized surface region.

In some embodiments, each row of non-metallized surface region, that spaces-apart each pair of two adjacent rows of electrical finger contacts, has a plurality of non-transcending trenches that penetrate into some, but not all, of a semiconductor layer of the PV cell; wherein each column of non-metallized surface region, that spaces-apart each pair of two adjacent electrical finger contacts, has a plurality of non-transcending trenches that penetrate into some, but not all, of said semiconductor layer of the PV cell.

In some embodiments, segmentation grooves run along each row of non-metallized surface region, that spaces-apart each pair of two adjacent rows of electrical finger contacts; wherein segmentation grooves run along each column of non-metallized surface region, that spaces-apart each pair of two adjacent electrical finger contacts; wherein segmentation grooves do not penetrate through any electrical finger contacts.

In some embodiments, said pre-defined pattern of discrete, metallized, electrical finger contacts, excludes and does not include any elongated metal wire that runs from a first edge of the PV cell to a second, opposite, edge of the PV cell; and comprises dashed segments of metallized contacts that are spaced apart from each other; wherein a length of each discrete, spaced apart, metallized contact is smaller than 10 percent of a total length of the PV cell.

In some embodiments, at least some of said discrete, metallized, electrical finger contacts, have a shape other than a shape of a single linear segment.

In some embodiments, at least some of said discrete, metallized, electrical finger contacts, have a shape selected from the group consisting of: Z-shape, V-shape, U-shape, O-shape, M-shape, W-shape, H-shape, S-shape, 5-Shape, star shape, asterisk shape.

In some embodiments, at least some of said discrete, metallized, electrical finger contacts are contacts that penetrate through particularly-placed openings in a dielectric coating layer.

In some embodiments, each of said discrete, metallized, electrical finger contacts, is located exactly on top of a selectively-constrained N-doped region of the top surface of the PV cell, and is surrounded by nearby P-type bulk silicon regions of the surface of the PV cell.

Some embodiments provide a method of producing a flexible photovoltaic (PV) cell, the method comprising: providing a P-type silicon bulk, which is a base region of the PV cell; selectively applying an N-type dopant, only to pre-defined constrained regions of a top region of said P-type silicon bulk, and creating there constrained N-type silicon regions that are scattered among P-type silicon bulk.

In some embodiments, the step of selectively applying the N-type dopant is performed by: placing, over the top surface of the P-type silicon bulk, a mask having pre-defined openings and having unopened regions; depositing said N-type dopant or an N-type dopant-containing layer, only through said openings of said mask, onto the top surface of the P-type silicon, while preventing deposition of said N-type dopant or said N-type dopant-containing layer onto neighboring bulk silicon regions that are beneath the unopened regions of said mask.

In some embodiments, the step of selectively applying said dopant is performed by: selectively depositing discrete amounts of an N-type dopant-containing paste, onto particular pre-defined regions of the top surface of the P-type silicon bulk.

In some embodiments, the step of selectively applying said dopant is performed by an ion implantation process that is configured to selectively implant N-type ions only into particular pre-defined regions of the top surface of the P-type silicon bulk.

In some embodiments, the method comprises: performing a selective and location-based metallization process, by placing a metal finger contact only on said particular N-type silicon regions of the top surface of the PV cell that are doped with said N-type dopant, and by maintaining free of metal finger contacts other regions of the top surface of the PV cell.

In some embodiments, the method comprises: performing a process that prevents or reduces recombination, at or near exposed surfaces of the PV cell.

In some embodiments, the process comprises: spreading or depositing a dopant-containing solution, on a surface of the PV cell that is intended to be segmented or grooved or trenched; drying the dopant-containing solution on said surface of the PV cell, and forming a dopant-containing layer on said surface of the PV cell; selectively and locally heating particular regions or lines of said surface of the PV cell; and performing grooving or trenching operations at said particular regions or lines of said surface of the PV cell that were selectively and locally heated.

In some embodiments, the process comprises: producing a not-yet-diced (or not-yet-trenched, or not-yet-grooved, or not-yet-segmented) PV cell; coating a surface of said not-yet-diced (or not-yet-trenched, or not-yet-grooved, or not-yet-segmented) PV cell, with a dopant-containing coating layer; grooving or trenching a plurality of trenches, through said dopant-containing coating layer, into the P-type silicon bulk of said not-yet-diced PV cell; wherein each trench penetrates into some, but not all, of the thickness of said P-type silicon bulk; dicing said PV cell along particular dicing lines that run among said trenches and do not run through said trenches; performing thermal drive-in or laser-based drive-in, at said exposed surfaces of said trenches.

In some embodiments, the process comprises: producing a not-yet-diced (or not-yet-trenched, or not-yet-grooved, or not-yet-segmented) PV cell; grooving a plurality of trenches, through said dopant-containing coating layer, into a silicon layer of said not-yet-diced PV cell; wherein each trench penetrates into some, but not all, of the thickness of said silicon layer; forming a dopant-containing protection layer that covers exposed surfaces of said trenches; performing thermal drive-in or laser-based drive-in, at said exposed surfaces of said trenches.

In some embodiments, the process comprises: subsequent to formation of said trenches, forming a passivation protection layer that covers exposed surfaces of said trenches, by performing chemical passivation of said exposed surfaces of said trenches.

In some embodiments, the process comprises: subsequent to formation of said trenches, forming a passivation protection layer that covers exposed surfaces of said trenches, by performing doping of said exposed surfaces of said trenches, followed by heating or annealing, to create a potential barrier that rejects electrons and provides a field-effect based passivation protection layer.

In some embodiments, the method comprises: partially covering a top surface of said PV cell with a pre-defined pattern of discrete, segmented, metallized, electrical finger contacts that are spaced apart from each other.

In some embodiments, the method comprises: producing said pre-defined pattern of discrete, metallized, electrical finger contacts, wherein said pattern comprise: generally parallel rows of discrete, metallized, electrical finger contacts; wherein each pair of two adjacent rows of electrical finger contacts, are spaced-apart by a row of non-metallized surface region; wherein each pair of two adjacent electrical finger contacts, are spaced-apart by a column of non-metallized surface region.

In some embodiments, the method comprises: (a) performing grooving of a plurality of non-transcending trenches, that penetrate into some, but not all, of a semiconductor layer of the PV cell, precisely at the non-metallized surface region, that spaces-apart each pair of two adjacent rows of electrical finger contacts; and (b) performing grooving of a plurality of non-transcending trenches, that penetrate into some, but not all, of the semiconductor layer of the PV cell, precisely at the non-metallized surface region, that spaces-apart each pair of two adjacent electrical finger contacts.

In some embodiments, the method comprises: producing a set of dashed, segmented, spaced-apart, electrical finger contacts that are arranged in spaced-apart rows; wherein a length of each discrete, spaced apart, metallized contact is smaller than 10 percent of a total length of the PV cell.

In some embodiments, at least some of said discrete, metallized, electrical finger contacts, have a shape other than a shape of a single linear segment.

In some embodiments, the method comprises: forming said discrete, metallized, electrical finger contacts by pouring or depositing metallic paste into pre-defined particularly-placed openings in a dielectric coating layer that covers a surface of said PV cell.

In some embodiments, the method comprises: forming said discrete, metallized, electrical finger contacts by selectively placing each metallized contact exactly and only on top of a selectively-constrained N-type doped silicon region of the front region of the PV cell.

Some embodiments provide improved flexible solar panels and photovoltaic devices, and methods and systems for producing them. A solar cell has non-transcending grooves or trenches, that penetrate some, but not all, of a silicon layer or semiconductor body or semiconductor wafer of the solar cell. The non-transcending grooves or trenches are segmenting the solar cell into regions, and contribute to its flexibility and mechanical resilience. Selective and localized region-constrained doping is performed at particular locations of a surface of the solar cell; as well as selective and localized placement of metallized electrical contacts. Grooving or trenching operations can be performed via a dopant-containing layer, to prevent or reduce recombination at or near exposed surfaces; or additional localized doping may be performed subsequent to such grooving or trenching. A particular layout of metallization is used for producing electrical contacts or “fingers” that are dashed or segmented or spaced-apart; such that grooving lines or trenching lines or segmentation lines are located along non-metallized gaps between adjacent contacts and between adjacent rows of contacts.

Some embodiments provide a flexible Photovoltaic (PV) cell, comprising: a semiconductor body, having a base region and a front region; wherein the base region is N-type silicon; wherein the front region is N-type silicon having constrained and pre-defined regions that are P-type silicon. In some embodiments, the base region is native N-type silicon; wherein the pre-defined regions that are P-type silicon, in the front region, are pre-defined regions of bulk silicon (i) that were initially doped with boron to become N-type regions as part of the N-type silicon bulk, and (ii) that subsequently were doped with boron to become P-type regions. In some embodiments, the base region has non-transcending trenches that penetrate into between 50 to 99 percent of a total thickness of the base region, and that do not penetrate into an entirety of the total thickness of the base region; wherein said non-transcending trenches in the base region increase flexibility and mechanical resilience and mechanical shock absorption of flexible said PV cell.

In some embodiments, polarities may be exchanged, or P-type and N-type may be exchanged; such that every portion of the discussion that mentions P-type may be read as mentioning N-type, as long as corresponding and related portions that discuss N-type are similar switched to being read as P-type; and as long as other suitable changes are made as needed (e.g., using boron for P-type doping; using phosphorus for N-type doping).

Additional Features, which May be Combined with any of the Above-Mentioned Features, and/or that May Implement any of the Above-Mentioned Features:

In accordance with some embodiments, each of the solar cells is rollable and flexible by itself; and is a single PV device or is a single PV article, that is comprised of a single semiconductor substrate or a single semiconductor wafer or a single semiconductor body; which is monolithic, e.g., is currently, and has been, a single item or a single article or a single component that was formed as (and remained) a single component; such that each solar cell is not formed as a collection or two or more separate units or as a collection of two or more entirely-separated or entirely-discrete or entirely-gapped units that were arranged or placed together in proximity to each other yet onto a metal foil or onto a metal film or onto a flexible or elastic foil or film.

In some embodiments, each single solar cell that is flexible and rollable by itself, is not a collection and is not an arrangement and is not an assembly of multiple discrete solar cells of PV modules, that each one of them has its own discrete and fully separated semiconductor substrate and/or its own discrete and fully separated semiconductor wafer and/or its own discrete and fully separated semiconductor body, and that have been merely placed to assembled or arranged together (or mounted together, or connected together) onto or beneath a flexible foil or a flexible film; but rather, the each single solar cell has a single unified semiconductor substrate or semiconductor body or semiconductor wafer that is common to, and is shared by, all the sub-regions or areas or portions of that single solar cell which includes therein (in that unified single semiconductor substrate or wafer or body) those non-transcending craters or non-transcending gaps or “blind gaps” that penetrate only from one side (and not from both sides), which do not reach all the way through and do not reach all the way to the other side of the unified single semiconductor substrate or wafer or body.

In some embodiments, each solar cell may be, or may include, a mono-crystalline PV cell or solar panel or solar cell, a poly-crystalline PV cell or solar panel or solar cell, a flexible PV cell or solar cell that is an Interdigitated Back Contact (IBC) solar cell having said semiconductor wafer with said set of non-transcending gaps, and/or other suitable type of PV cell or solar cell.

Some portions of the discussion above and/or herein may relate to regions or segments or areas, of the semiconductor body or substrate or wafer (or PV cell, or PV device); yet those “segments” are still touching each other and/or inherently connected to each other and/or non-separated from each other, as those “segments” are still connected by at least a thin portion or a thin bottom-side surface of the semiconductor substrate (or wafer, or body), which still holds and includes at least 1 (or at least 2, or at least 3, or at least 5, or at least 10, or at least 15, or at least 20, or at least 25, or at least 33; but not more than 50, or not more than 40) percent of the entire depth or the entire thickness (or the maximum thickness or depth) of the semiconductor substrate or body or wafer; as those “segments” are still connected at their base through such thin layer, and those “segments” have between them (or among them) the non-transcending gaps or the “blind gaps” or the non-transcending craters that thus separate those “segments” but that do not fully divide or fully break or fully isolate any two such neighboring “segments” from each other. Upon its production, and prior to attaching the solar cells onto the floating medium layer, each such flexible and rollable solar cell is freestanding and carrier-less and non-supported.

In some embodiments, the non-transcending gaps or the “blind gaps” or craters or slits or grooves, are introduced and are formed only at a first side or at a first surface of the semiconductor substrate or body or wafer, and are not formed at both of the opposite surfaces (or sides) thereof.

In some embodiments, the non-transcending gaps or the “blind gaps” or craters or slits or grooves, are introduced and are formed only at a first side or at a first surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; and they are not formed at the other (e.g., opposite, non-active) side or surface (e.g., the side that is not intended to be facing the sunlight or the light, or the side that is not intended to be producing electricity based on the PV effect).

In other embodiments, the non-transcending gaps or the “blind gaps” or craters or slits or grooves, are not introduced and are not formed at the side or surface of the semiconductor substrate or body or wafer, that is intended to face the sunlight or the light, or that is the active side of the PV device or PV cell, or that is intended to be the active side of the PV device or PV cell, or that is intended to be the electricity-generating side or surface that would generated electricity based on incoming sunlight or light or based on the PV effect; but rather, those non-transcending gaps or the “blind gaps” or craters or slits or grooves are formed at the other (e.g., opposite, non-active) side or surface, which is the side that is not intended to be facing the sunlight or the light, or the side that is not intended to be producing electricity based on the PV effect. Some implementations with this structure may advantageously provide the mechanical shock absorption and the mechanical forces dissipation capability, yet may also provide or maintain or achieve an increased level of PV-based electricity production since the gaps do not reduce the area of the light-exposed side or the light-facing side of the PV device.

In still other embodiments, the non-transcending gaps or the “blind gaps” or craters or slits or grooves, are introduced and are formed at both sides or at both surfaces of the semiconductor substrate or body or wafer; yet with an offset among the gaps of the first side and the gaps of the second side, in a zig-zag pattern of those gaps which zig-zag across the two sides of the semiconductor wafer or substrate or body; for example, a first gap located at the top surface on the left; then, a second gap located at the bottom surface to the right side of the first gap and not overlapping at all with the first gap; then, a third gap located at the top surface to the right side of the second gap and not overlapping at all with the second gap; then, a fourth gap located at the bottom surface to the right side of the third gap and not overlapping at all with the third gap; and so forth. In such structure, for example, any single point or any single location or any single region of the remaining semiconductor wafer or substrate or wafer, may have a gap or a crater or a “blind gap” only on one of its two sides, but not on both of its sides.

In yet other embodiments, the non-transcending gaps or the “blind gaps” or craters or slits or grooves, are introduced and are formed at both sides or at both surfaces of the semiconductor substrate or body or wafer; not necessarily with an offset among the gaps of the first side and the gaps of the second side, and not necessarily in a zig-zag pattern; but rather, by implementing any other suitable structure or pattern that still provides the mechanical shock resilience, and while also maintaining a sufficiently-thin layer of semiconductor substrate or body or wafer that is not removed and that is resilient to mechanical shocks and mechanical forces due to the craters or gaps that surround it.

Some embodiments may include and/or may utilize one or more units, devices, connectors, wires, electrodes, and/or methods which are described in United States patent application publication number US 2016/0308155 A1, which is hereby incorporated by reference in its entirety. For example, some embodiments may include and may utilize an electrode arrangement which is configured to define or create a plurality of electricity collection regions, such that within each of the collection regions, at least two sets of conducting wires are provided such that they are insulated from each other, and the at least two sets of conducting wires are connected either in parallel or in series between the collection regions to thus provide accumulating voltage of charge collection. Some embodiments may include an electric circuit for reading-out or collection or aggregation of the generated electricity, configured as an electrodes arrangement, including conducting wires arranged in the form of nets covering zones of a pre-determined area. The electrodes arrangement may be configured or structured to be stretched (e.g., rolled out) along the surface of the PV cell, and may be formed by at least two sets of conducting wires, and may cover a plurality of collection zones or collection regions.

Within each of the electricity collection zones or electricity aggregation zones, the different conducting wires are insulated from each other, to provide a certain voltage between them. At a transition between zones, the negative charges collecting conductive wire of one zone, is electrically connected to the positive charges collecting conductive wire of the adjacent or the consecutive zone. Thus, within each of the collection zones, the different sets of conducting wires are insulated from each other, while being connected in series between the zones. This configuration of the electrode arrangement allows accumulation or aggregation of electric voltage generated by charge collection along the surface of the PV device. The configuration of the electrode arrangement provides a robust electric collection structure.

The internal connections between the sets of conducting wires allow energy collection even if the surface being covered is not continuous, e.g., if a perforation occurs in the structure of the net. This feature of the electrode arrangement allows for using this technique on any surface exposed to photon radiation, while also allowing discontinuity if needed and without limiting or disrupting the electric charge collection.

In some embodiments, a set of conducting wires may be embedded in or within a flexible and/or adhesive and/or transparent-to-light plastic foil or plastic film or encapsulant, is embedded immediately beneath such film or foil or encapsulant, or immediately over such film or foil or encapsulant, or is included within such film or foil or encapsulant (e.g., such that the plastic or encapsulant is to the right and to the left of each conducting wire but does not obstruct and does not prevent the conducting wire from touching the solar cell surface for collecting electric charge therefrom). In some embodiments, the sunny-side surface and/or the dark-side surface of each solar cell, or the top-side and/or the bottom-side of each solar cell, may be coated with an adhesive or a transparent adhesive and/or with an electrically-conducting adhesive and/or an electrically-conducting transparent adhesive, to enable gluing or bonding of such surface of the PV cell to the set of conducting wires, for long-term bonding or at least for short-term bonding during the production process before the plastic foil is heated and/or before the PV cell is laminated or encapsulated.

In some embodiments, some, or all, or a majority of, the non-transcending craters or “blind gaps”, are filled with one or more filler material(s), which further provide mechanical shock absorption and/or mechanical shock dissipation and/or thermal resilience and/or mechanical resilience and/or physical resilience and/or chemical resilience and/or mechanical durability and/or thermal durability and/or physical durability and/or chemical durability.

In some embodiments, each of the solar cells in the array, and/or the entirety of the array of solar cells, is laminated and/or encapsulated, within a single lamination layer or a single encapsulation layer, or within two or more layers or coatings or encapsulants, which may be transparent and enable light to pass there-through, or which may be translucent and may enable at least 75% of light to pass there-through, and which may provide further mechanical resilience and damage protection to the solar cells and their array.

In some embodiments, a device comprises a self-floating, rollable, flexible, photovoltaic article, that is formed of a plurality of flexible and rollable and mechanically-resilient solar cells that are inter-connected as a generally planar (yet flexible and rollable) array. Each of said flexible and rollable and mechanically-resilient solar cells has (I) a sunny-side or top-side surface that is configured to absorb light, and (II) a back-side or bottom-side surface that is opposite to said sunny-side surface and is not necessarily configured to absorb light (e.g., in some implementations it does not absorb light and it is a “dark side”; or, in other implementations, it also absorbs light and it is a “sunny side”). Each of said flexible and rollable and mechanically-resilient solar cells is configured to generate electric current from light via the photovoltaic effect.

The terms “plurality” and “a plurality”, as used herein, include, for example, “multiple” or “two or more”. For example, “a plurality of items” includes two or more items.

References to “one embodiment”, “an embodiment”, “demonstrative embodiment”, “various embodiments”, “some embodiments”, and/or similar terms, may indicate that the embodiment(s) so described may optionally include a particular feature, structure, or characteristic, but not every embodiment necessarily includes the particular feature, structure, or characteristic. Furthermore, repeated use of the phrase “in one embodiment” does not necessarily refer to the same embodiment, although it may. Similarly, repeated use of the phrase “in some embodiments” does not necessarily refer to the same set or group of embodiments, although it may.

As used herein, and unless otherwise specified, the utilization of ordinal adjectives such as “first”, “second”, “third”, “fourth”, and so forth, to describe an item or an object, merely indicates that different instances of such like items or objects are being referred to; and does not intend to imply as if the items or objects so described must be in a particular given sequence, either temporally, spatially, in ranking, or in any other ordering manner.

Functions, operations, components and/or features described herein with reference to one or more embodiments, may be combined with, or may be utilized in combination with, one or more other functions, operations, components and/or features described herein with reference to one or more other embodiments. Some embodiments may thus comprise any possible or suitable combinations, re-arrangements, assembly, re-assembly, or other utilization of some or all of the modules or functions or components that are described herein, even if they are discussed in different locations or different chapters of the above discussion, or even if they are shown across different drawings or multiple drawings.

While certain features of some demonstrative embodiments have been illustrated and described herein, various modifications, substitutions, changes, and equivalents may occur to those skilled in the art. Accordingly, the claims are intended to cover all such modifications, substitutions, changes, and equivalents.

1. A flexible Photovoltaic (PV) cell, comprising:
a semiconductor body, having a base region and a front region;
wherein the base region is P-type silicon;
wherein the front region is P-type silicon having constrained and pre-defined regions that are N-type silicon.

2. The flexible PV cell according to claim 1,
wherein the base region is native P-type silicon;
wherein the pre-defined regions that are N-type silicon, in the front region, are pre-defined regions of bulk silicon (i) that were initially doped with boron to become P-type regions as part of the P-type silicon bulk, and (ii) that subsequently were doped with phosphorus to become N-type regions.

3. The flexible PV cell according to claim 2,
wherein the base region has non-transcending trenches that penetrate into between 50 to 99 percent of a total thickness of the base region, and that do not penetrate into an entirety of the total thickness of the base region;
wherein said non-transcending trenches in the base region increase flexibility and mechanical resilience and mechanical shock absorption of flexible said PV cell.

4. The flexible PV cell according to claim 2,
wherein the base region has non-transcending trenches that penetrate into between 50 to 99 percent of a total thickness of the semiconductor body, and that do not penetrate into an entirety of the total thickness of the semiconductor body;
wherein said non-transcending trenches in the base region increase flexibility and mechanical resilience and mechanical shock absorption of flexible said PV cell.

5. The flexible PV cell according to claim 4,
wherein at least some of said non-transcending trenches contain a filler material having mechanical force absorption properties, which provides mechanical shock absorption properties to said flexible PV cell.

6. The flexible PV cell according to claim 2,
wherein the flexible PV cell is a Passivated Emitter and Rear Contact (PERC) PV cell,
wherein the base region is a P-type silicon having a particular thickness in a range of 100 to 250 microns;
wherein the front region is a silicon layer, having a thickness in a range of 0.3 to 0.5 microns, and comprises said N-type silicon regions that are scattered among P-type silicon regions located at a same plane.

7. The flexible PV cell according to claim 4,
wherein each trench is tapered inwardly and is generally V-shaped or U-shaped.

8. The flexible PV cell according to claim 7,
wherein a width value of the widest opening of each trench is in a range of 30 to 50 microns.

9. The flexible PV cell according to claim 8,
wherein exposed surfaces of each trench are doped with boron or phosphorus to reduce recombination at, or in proximity to, said exposed surfaces.

10. The flexible PV cell according to claim 4,
wherein the front region, which comprises said pre-defined N-type silicon regions, also has a set of additional trenches, that penetrate inwardly through an entirety of a depth of the N-type regions and further penetrate into some, but not all, of the thickness of the P-type base region;
wherein trenches that penetrate downwardly into the pre-defined N-type silicon regions, do not meet with trenches that penetrate upwardly into the P-type silicon layer.

11. The flexible PV cell according to claim 10,
wherein at least some of the trenches that penetrate into the front region that comprises said pre-defined N-type silicon regions, contain a trench filler material that is configured to increase mechanical resilience and mechanical forces absorption properties of said PV cell.

12. The flexible PV cell according to claim 1,
wherein discrete, metallized, electrical finger contacts are located exactly on top of said pre-defined N-type silicon regions of the front region, and are not located on top of P-type silicon bulk that surrounds each of the pre-defined N-type silicon regions of the front regions.

13. The flexible PV cell according to claim 1,
wherein the front region is covered by a pre-defined pattern of discrete, metallized, electrical finger contacts, which comprises:
generally parallel rows of discrete, metallized, electrical finger contacts;
wherein each pair of two adjacent rows of electrical finger contacts, are spaced-apart by a row of non-metallized surface region;
wherein each pair of two adjacent electrical finger contacts, are spaced-apart by a column of non-metallized surface region.

14. The flexible PV cell according to claim 13,
wherein each row of non-metallized surface region, that spaces-apart each pair of two adjacent rows of electrical finger contacts, has a plurality of non-transcending trenches that penetrate into some, but not all, of a semiconductor layer of the PV cell;
wherein each column of non-metallized surface region, that spaces-apart each pair of two adjacent electrical finger contacts, has a plurality of non-transcending trenches that penetrate into some, but not all, of said semiconductor layer of the PV cell.

15. The flexible PV cell according to claim 14,
wherein segmentation grooves run along each row of non-metallized surface region, that spaces-apart each pair of two adjacent rows of electrical finger contacts;
wherein segmentation grooves run along each column of non-metallized surface region, that spaces-apart each pair of two adjacent electrical finger contacts;
wherein segmentation grooves do not penetrate through any electrical finger contacts.

16. The flexible PV cell according to claim 13,
wherein said pre-defined pattern of discrete, metallized, electrical finger contacts,
excludes and does not include any elongated metal wire that runs from a first edge of the PV cell to a second, opposite, edge of the PV cell;
and comprises dashed segments of metallized contacts that are spaced apart from each other;
wherein a length of each discrete, spaced apart, metallized contact is smaller than 10 percent of a total length of the PV cell.

17. The flexible PV cell according to claim 13,
wherein at least some of said discrete, metallized, electrical finger contacts,
have a shape other than a shape of a single linear segment.

18. The flexible PV cell according to claim 13,
wherein at least some of said discrete, metallized, electrical finger contacts,
have a shape selected from the group consisting of: Z-shape, V-shape, U-shape, O-shape, M-shape, W-shape, H-shape, S-shape, 5-Shape, star shape, asterisk shape.

19. The flexible PV cell according to claim 13,
wherein at least some of said discrete, metallized, electrical finger contacts are contacts that penetrate through particularly-placed openings in a dielectric coating layer.

20. The flexible PV cell according to claim 13,
wherein each of said discrete, metallized, electrical finger contacts,
is located exactly on top of a selectively-constrained N-doped region of the top surface of the PV cell, and is surrounded by nearby P-type bulk silicon regions of the surface of the PV cell.

21. A method of producing a flexible photovoltaic (PV) cell,
the method comprising:
providing a P-type silicon bulk, which is a base region of the PV cell;
selectively applying an N-type dopant, only to pre-defined constrained regions of a top region of said P-type silicon bulk, and creating there constrained N-type silicon regions that are scattered among P-type silicon bulk.

22. The method according to claim 21,
wherein the step of selectively applying the N-type dopant is performed by:
placing, over the top surface of the P-type silicon bulk, a mask having pre-defined openings and having unopened regions;
depositing said N-type dopant or an N-type dopant-containing layer, only through said openings of said mask, onto the top surface of the P-type silicon, while preventing deposition of said N-type dopant or said N-type dopant-containing layer onto neighboring bulk silicon regions that are beneath the unopened regions of said mask.

23. The method according to claim 21,
wherein the step of selectively applying said N-type dopant is performed by:
selectively depositing discrete amounts of an N-type dopant-containing paste, onto particular pre-defined regions of the top surface of the P-type silicon bulk.

24. The method according to claim 21,
wherein the step of selectively applying said N-type dopant is performed by an ion implantation process that is configured to selectively implant N-type ions only into particular pre-defined regions of the top surface of the P-type silicon bulk.

25. The method according to claim 21, further comprising:
performing a selective and location-based metallization process,
by placing a metal finger contact only on said particular N-type silicon regions of the top surface of the PV cell that are doped with said N-type dopant,
and by maintaining free of metal finger contacts other regions of the top surface of the PV cell.

26. The method according to claim 24, comprising:
performing a Recombination Prevention/Reduction Process that prevents or reduces recombination, at or near exposed surfaces of the PV cell.

27. The method according to claim 26, comprising:
spreading or depositing a dopant-containing solution, on a surface of the PV cell that is intended to be segmented or grooved or trenched;
drying the dopant-containing solution on said surface of the PV cell, and forming a dopant-containing layer on said surface of the PV cell;
selectively and locally heating particular regions or lines of said surface of the PV cell; and performing grooving or trenching operations at said particular regions or lines of said surface of the PV cell that were selectively and locally heated.

28. The method according to claim 26, comprising:
producing a not-yet-diced PV cell;
coating a surface of said not-yet-diced PV cell, with a dopant-containing coating layer;
grooving a plurality of trenches, through said dopant-containing coating layer, into the P-type silicon bulk of said not-yet-diced PV cell; wherein each trench penetrates into some, but not all, of the thickness of said P-type silicon bulk;
dicing said PV cell along particular dicing lines that run among said trenches and do not run through said trenches;
performing thermal drive-in or laser-based drive-in, at said exposed surfaces of said trenches.

29. The method according to claim 26, comprising:
producing a not-yet-diced PV cell;
grooving a plurality of trenches, through said dopant-containing coating layer, into a silicon layer of said not-yet-diced PV cell; wherein each trench penetrates into some, but not all, of the thickness of said silicon layer;
forming a dopant-containing protection layer that covers exposed surfaces of said trenches;
performing thermal drive-in or laser-based drive-in, at said exposed surfaces of said trenches.

30. The method according to claim 29, comprising:
subsequent to formation of said trenches, forming a passivation protection layer that covers exposed surfaces of said trenches, by performing chemical passivation of said exposed surfaces of said trenches.

31. The method according to claim 29, comprising:
subsequent to formation of said trenches, forming a passivation protection layer that covers exposed surfaces of said trenches, by performing doping of said exposed surfaces of said trenches, followed by heating or annealing, to create a potential barrier that rejects electrons and provides a field-effect based passivation protection layer.

32. The method according to claim 21, comprising:
partially covering a top surface of said PV cell with a pre-defined pattern of discrete, segmented, metallized, electrical finger contacts that are spaced apart from each other.

33. The method according to claim 32, comprising:
producing said pre-defined pattern of discrete, metallized, electrical finger contacts, wherein said pattern comprise:
generally parallel rows of discrete, metallized, electrical finger contacts;
wherein each pair of two adjacent rows of electrical finger contacts, are spaced-apart by a row of non-metallized surface region;
wherein each pair of two adjacent electrical finger contacts, are spaced-apart by a column of non-metallized surface region.

34. The method according to claim 32, comprising:
(a) performing grooving of a plurality of non-transcending trenches, that penetrate into some, but not all, of a semiconductor layer of the PV cell,
precisely at the non-metallized surface region, that spaces-apart each pair of two adjacent rows of electrical finger contacts;
and
(b) performing grooving of a plurality of non-transcending trenches, that penetrate into some, but not all, of the semiconductor layer of the PV cell,
precisely at the non-metallized surface region, that spaces-apart each pair of two adjacent electrical finger contacts.

35. The method according to claim 32, comprising:
producing a set of dashed, segmented, spaced-apart, electrical finger contacts that are arranged in spaced-apart rows;
wherein a length of each discrete, spaced apart, metallized contact is smaller than 10 percent of a total length of the PV cell.

36. The method according to claim 32, comprising:
wherein at least some of said discrete, metallized, electrical finger contacts,
have a shape other than a shape of a single linear segment.

37. The method according to claim 32, comprising:
forming said discrete, metallized, electrical finger contacts by pouring or depositing metallic paste into pre-defined particularly-placed openings in a dielectric coating layer that covers a surface of said PV cell.

38. The method according to claim 32, comprising:
forming said discrete, metallized, electrical finger contacts by selectively placing each metallized contact exactly and only on top of a selectively-constrained N-type doped silicon region of the front region of the PV cell.

39. A flexible Photovoltaic (PV) cell, comprising:
a semiconductor body, having a base region and a front region;
wherein the base region is N-type silicon;
wherein the front region is N-type silicon having constrained and pre-defined regions that are P-type silicon.

40. The flexible PV cell according to claim 39,
wherein the base region is native N-type silicon;
wherein the pre-defined regions that are P-type silicon, in the front region, are pre-defined regions of bulk silicon (i) that were initially doped with boron to become N-type regions as part of the N-type silicon bulk, and (ii) that subsequently were doped with boron to become P-type regions.

41. The flexible PV cell according to claim 40,
wherein the base region has non-transcending trenches that penetrate into between 50 to 99 percent of a total thickness of the base region, and that do not penetrate into an entirety of the total thickness of the base region;
wherein said non-transcending trenches in the base region increase flexibility and mechanical resilience and mechanical shock absorption of flexible said PV cell.
